(19) United States
(12) Patent Application Publication
(10) Pub. No.: US 2022/0267484 A1
(43) Pub. Date: Aug. 25, 2022

(54) PHOTOSENSITIVE RESIN COMPOSITION, PHOTOSENSITIVE RESIN FILM, METHOD FOR PRODUCING CURED PRODUCT, LAMINATE, AND ELECTRONIC COMPONENT

(71) Applicant: Showa Denko Materials Co., Ltd., Chiyoda-ku, Tokyo (JP)

(72) Inventors: Mao NARITA, Chiyoda-ku, Tokyo (JP); Keishi ONO, Chiyoda-ku, Tokyo (JP); Tatsuhiko ARAI, Chiyoda-ku, Tokyo (JP); Naoto KURODA, Chiyoda-ku, Tokyo (JP)

(21) Appl. No.: 17/624,846

(22) PCT Filed: Jul. 10, 2019
(86) PCT No.: PCT/JP2019/027412

§ 371 Date: Jan. 5, 2022

(51) Int. Cl. C08F 2/50; C08F 2/44; C08F 16/36; C08F 220/34; C07F 9/53; C08K 5/5415; C08K 5/3475

(52) U.S. Cl. CPC C08F 2/50; C08F 2/44; C08F 16/36; C08F 220/343; C07F 9/53; C08K 5/5415; C08K 5/3475; C08F 2810/20; H01F 27/323

(57) ABSTRACT

A photosensitive resin composition containing: a component (A) which is a high molecular weight compound having a photopolymerizable functional group and a carbon-nitrogen bond; a component (B) which is a low molecular weight compound having a photopolymerizable functional group; a component (C) which is a photopolymerization initiator; and a component (D) which is a triazole-based compound.

### TECHNICAL FIELD

The present disclosure relates to a photosensitive resin composition, a photosensitive resin film, a method for producing a cured product, a laminate, and an electronic component.

### BACKGROUND ART

In the field of manufacturing semiconductor integrated circuits (LSIs) or wiring boards, photosensitive materials are used as resists for producing conductor patterns. For example, in the manufacturing of a wiring board, a resist is formed using a photosensitive resin composition, and then a conductor pattern, a metal post, and the like are formed by a plating treatment. More specifically, a photosensitive layer is formed on a support (substrate) using a photosensitive resin composition or the like, and the photosensitive layer is exposed through a predetermined mask pattern, and then is subjected to a developing treatment so that a part forming a conductor pattern, a metal post, and the like can be selectively removed (peeled), thereby forming a resist pattern (resist). Next, a conductor such as copper is formed on the removed part by a plating treatment, and then a wiring board including a conductor pattern, a metal post, and the like can be manufactured by removing the resist pattern.

Conventionally, by growing metal plating after the resist pattern is removed, a thick conductor pattern and a metal post have been produced. In order to meet such requirements, for example, as a photosensitive resist for thick films, a photosensitive layer having a thickness of about 30 μm, or a thickness of about 65 μm at the maximum, has been used (see Patent Literatures 1 and 2).

Furthermore, in recent years, in order to further improve performance, it has been attempted to form a thick conductor layer having a thickness of about 150 μm by subjecting a layer, which exists in a direction in which the layer is desired to be selectively grown by plating, among metal ion-poor layers to a plating treatment while being destroyed by a plating solution (see Patent Literature 3).

### CITATION LIST

### Patent Literature

Patent Literature 1: Japanese Unexamined Patent Publication No. 2015-034926

Patent Literature 2: Japanese Unexamined Patent Publication No. 2014-074774

Patent Literature 3: Japanese Unexamined Patent Publication No. 2014-080674

### SUMMARY OF INVENTION

### Technical Problem

However, in the conventional photosensitive resist for thick films, for example, in a case where a thick photosensitive layer having a thickness of 70 μm or more is required to be formed, light is difficult to pass through to the bottom, and the pattern shape deteriorates in some cases. Furthermore, in the method described in Patent Literature 3, since plating is advanced while the metal ion-poor layer is partially destroyed, it is difficult to stably form an excellent pattern. Therefore, even in the case of forming a photosensitive layer having a thickness of 70 μm, and further, 150 μm that is thicker than that in a conventional case, or 150 μm or more (a thickness in a direction perpendicular to a substrate), a photosensitive resist having excellent pattern formability is required.

Furthermore, a copper wiring is mounted on a substrate of an electronic component such as an inductor. In the case of forming a resist pattern on such a substrate having a copper wiring, there is a problem in that development residue is likely to be generated on a copper surface after development. Particularly, in the case of thickening the photosensitive layer, the above-described development residue problem tends to be significant. Therefore, a photosensitive layer capable of suppressing the occurrence of such development residue on the copper surface is required.

Further, in the case of forming a resist pattern on a substrate having a copper wiring, in a photosensitive layer, it is required to realize excellent pattern formability on surfaces of both of a site where the copper wiring is formed and a site where the copper wiring is not formed. Furthermore, in a case where a photosensitive layer is formed on a substrate having a copper wiring and then exposed, it is necessary to perform exposure under the same exposure conditions without distinction between the site where the copper wiring is formed and the site where the copper wiring is not formed. When exposure conditions in which a high-resolution resist pattern can be formed are different between the site where the copper wiring is formed and the site where the copper wiring is not formed (there is a mismatch), a problem arises in that a uniform resist pattern cannot be formed. Therefore, in the photosensitive layer, it is further required to realize excellent pattern formability under the same exposure conditions on surfaces of both of the site where the copper wiring is formed and the site where the copper wiring is not formed.

The present disclosure has been made in view of the above circumstances, and an object thereof is to provide a photosensitive resin composition capable of suppressing the occurrence of development residue on a copper surface and capable of realizing excellent pattern formability under the same exposure conditions on surfaces of both of a site of a substrate having a copper surface and a site of the substrate not having a copper surface, and a photosensitive resin film, a method for producing a cured product, a laminate, and an electronic component which use the photosensitive resin composition (hereinafter, referred to as “photosensitive resin composition and the like” in some cases).

### Solution to Problem

The present inventors have conducted intensive studies in order to solve the above problems, and as a result, they have found that the problems can be solved by a photosensitive resin composition having the following configuration, and the like. The present disclosure provides the following photosensitive resin composition and the like.

[1] A photosensitive resin composition containing: a component (A) which is a high molecular weight compound having a photopolymerizable functional group and a carbon-nitrogen bond; a component (B) which is a low molecular weight compound having a photopolymerizable functional group; a component (C) which is a photopolymerization initiator; and a component (D) which is a triazole-based compound.

[2] The photosensitive resin composition described in the above [1], in which the component (D) comprises a benzotriazole-based compound.

[3] The photosensitive resin composition described in the above [1] or [2], in which a content of the component (D) is 0.1 to 10% by mass based on a total amount of solid contents of the photosensitive resin composition.

[4] The photosensitive resin composition described in any one of the above [1] to [3], in which the component (A) comprises a high molecular weight compound having a (meth)acryloyl group as the photopolymerizable functional group.

[5] The photosensitive resin composition described in any one of the above [1] to [4], in which the component (A) comprises a high molecular weight compound having a urethane bond as the carbon-nitrogen bond.

[6] The photosensitive resin composition described in any one of the above [1] to [5], in which the component (A) comprises a high molecular weight compound having six or more ethylenically unsaturated groups as the photopolymerizable functional group and having a weight average molecular weight of 2,500 or more.

[7] The photosensitive resin composition described in any one of the above [1] to [6], in which the component (A) comprises a high molecular weight compound having at least one skeleton selected from the group consisting of a chain hydrocarbon skeleton, an alicyclic skeleton, and an aromatic ring skeleton.

[8] The photosensitive resin composition described in any one of the above [1] to [7], in which the component (B) comprises at least one selected from the group consisting of a low molecular weight compound having a urethane bond, a low molecular weight compound having an isocyanuric ring, and a low molecular weight compound having an alicyclic skeleton.

[9] The photosensitive resin composition described in any one of the above [1] to [7], in which the component (B) comprises a low molecular weight compound having at least one (meth)acryloyl group and a urethane bond.

[10] The photosensitive resin composition described in any one of the above [1] to [9], in which the component (C) comprises a compound represented by General Formula (C1) below or a compound represented by General Formula (C2) below.

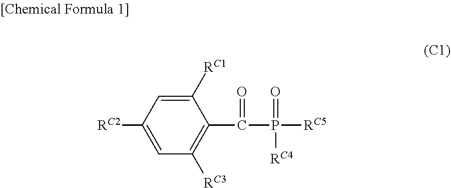

[R^{C1}, R^{C2}, and R^{C3} each independently represents a hydrogen atom, an alkyl group having 1 to 6 carbon atoms, or an alkoxy group having 1 to 6 carbon atoms; and R^{C8} and R^{C5} each independently represents a hydrogen atom, an alkyl group having 1 to 6 carbon atoms, an alkoxy group having 1 to 6 carbon atoms, or an aryl group having 6 to 12 carbon atoms; and each of R^{C1} to R^{C5} other than the hydrogen atom may have a substituent.]

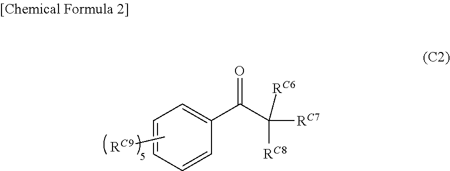

[R^{C6} represents a hydroxyl group, an alkoxy group having 1 to 6 carbon atoms, or an amino group; R^{C7} and R^{C8} each independently represents a hydrogen atom, an alkyl group having 1 to 8 carbon atoms, an aryl group having 6 to 12 carbon atoms, or an alkoxy group having 1 to 8 carbon atoms, R^{C7} and R^{C8} may be bonded to each other to form a cyclic structure having 3 to 16 carbon atoms; each of R^{C6} to R^{C8} other than the hydroxyl group and the hydrogen atom may have a substituent, in an amino group having a substituent, substituents may be bonded to each other to form a cyclic structure having 3 to 12 carbon atoms; and R^{C9}'s each independently represents a hydrogen atom, a halogen atom, a hydroxyl group, an amino group, a mercapto group, or an organic group having 1 to 10 carbon atoms which may contain one or more atoms selected from an oxygen atom, a nitrogen atom, and a sulfur atom.]

[11] The photosensitive resin composition described in any one of the above [1] to [10], further containing a component (E) which is a high molecular weight compound having a glass transition temperature of 70° C. to 150° C. and not having a carbon-nitrogen bond.

[12] The photosensitive resin composition described in any one of the above [1] to [11], further containing a component (F) which is a silane compound.

[13] A photosensitive resin film having a photosensitive layer using the photosensitive resin composition described in any one of the above [1] to [12].

[14] A method for producing a cured product, the method including: a step of providing a photosensitive layer on a substrate by using the photosensitive resin composition described in any one of the above [1] to [12] or the photosensitive resin film described in the above [13]; a step of irradiating at least a part of the photosensitive layer with an active ray to form a photocured part; and a step of removing at least a part of the photosensitive layer other than the photocured part to form a resin pattern, in the stated order.

[15] The method for producing a cured product described in the above [14], further including a step of heat-treating the resin pattern.

[16] The method for producing a cured product described in the above [14] or [15], in which a thickness of the resin pattern is 70 μm or more and 300 μm or less.

[17] The method for producing a cured product described in any one of the above [14] to [16], further including a step of heat-treating the photosensitive layer after the photosensitive layer is provided on a substrate.

[18] A laminate including a cured product of the photosensitive resin composition described in any one of the above [1] to [12].

[19] The laminate described in [18], in which a thickness of the cured product is 70 μm or more and 300 μm or less.

[20] An electronic component including a cured product of the photosensitive resin composition described in any one of the above [1] to [12].

### Advantageous Effects of Invention

According to the present disclosure, it is possible to provide a photosensitive resin composition capable of suppressing the occurrence of development residue on a copper surface and capable of realizing excellent pattern formability under the same exposure conditions on surfaces of both of a site of a substrate having a copper surface and a site of the substrate not having a copper surface, and the like.

### BRIEF DESCRIPTION OF DRAWINGS

FIG. 1 is a diagram illustrating a pattern shape of drawing data used in exposure by a direct drawing exposure apparatus in Examples.

### DESCRIPTION OF EMBODIMENTS

Hereinafter, the present disclosure will be specifically described.

In the present specification, a numerical range that has been indicated by use of “to” indicates the range that includes the numerical values which are described before and after “to”, as the minimum value and the maximum value, respectively. Furthermore, in the numerical ranges that are described stepwise in the present specification, the upper limit value or the lower limit value of the numerical range of a certain stage may be replaced with the upper limit value or the lower limit value of the numerical range of another stage. In the numerical ranges that are described in the present specification, the upper limit value or the lower limit value of the numerical value range may be replaced with the value shown in Examples.

In the present specification, “(meth)acrylic acid” means at least one of “acrylic acid” and the corresponding “methacrylic acid”, and the same applies to other analogous expressions such as (meth)acrylate.

In the present specification, “solid content” refers to a nonvolatile content of the photosensitive resin composition excluding volatile substances such as water and a solvent, refers to components remaining without volatile when the resin composition is dried, and also includes components present in a liquid, syrupy and waxy state at room temperature near 25° C.

[Photosensitive resin composition]

A photosensitive resin composition according to an embodiment in the present disclosure (hereinafter, simply referred to as the present embodiment in some cases) contains: a component (A) which is a high molecular weight compound having a photopolymerizable functional group and a carbon-nitrogen bond; a component (B) which is a low molecular weight compound having a photopolymerizable functional group; a component (C) which is a photopolymerization initiator; and a component (D) which is a triazole-based compound.

According to the photosensitive resin composition of the present embodiment, by containing the component (A) which is a high molecular weight compound having the above-described specific structure, the component (B) which is a low molecular weight compound having the above-described specific structure, the component (C) which is a photopolymerization initiator, and the component (D) which is a triazole-based compound, it is possible to suppress the occurrence of development residue on a copper surface and it is possible to realize excellent pattern formability under the same exposure conditions on surfaces of both of a site of a substrate having a copper surface and a site of the substrate not having a copper surface. The present inventors infer the reasons why such effects are obtainable as follows. That is, the triazole-based compound which is the component (D) has a property that nitrogen atoms in the triazole skeleton are easily coordinated to the copper surface of the substrate. Due to this high coordination ability to the copper surface, the triazole-based compound is likely to be unevenly distributed in the vicinity of the copper surface. As a result, a triazole-based compound layer having a high concentration of the triazole-based compound is formed on the surface of the photosensitive layer formed by using the photosensitive resin composition in contact with the copper surface. Further, it is considered that the presence of this triazole-based compound layer reduces a chance that other organic matters constituting the photosensitive resin composition come into contact with the copper surface, and it is possible to considerably suppress generation of development residue caused by the other organic matters adhering to the copper surface. Furthermore, the triazole-based compound is excellent in adhesion with the copper surface, can be easily removed by development, and does not impair the curability of the photosensitive resin composition. Therefore, even in the case of forming a thick photosensitive layer on the copper surface and forming a resist pattern with a fine line width and a narrow line space, excellent pattern formability can be realized. Furthermore, in the case of a high radical concentration in the reaction system such as the condition of a high exposure amount, it is considered that the hydrogen of the triazole-based compound is extracted to play a role as a polymerization inhibitor, and the process margin is widened, so that excellent pattern formability can be realized under the same exposure conditions in both of a substrate having a copper surface and a substrate not having a copper surface.

From the above description, according to the photosensitive resin composition of the present embodiment, even in the case of forming a thick photosensitive layer (for example, a thickness of 70 μm or more), excellent pattern formability can be realized under the same exposure conditions on surfaces of both of a site of a substrate having a copper surface and a site of the substrate not having a copper surface, and the occurrence of development residue on the copper surface can be suppressed.

Hereinafter, respective components constituting the photosensitive resin composition of the present embodiment will be described.

<Component (A): high molecular weight compound>

The photosensitive resin composition of the present embodiment contains a high molecular weight compound having a photopolymerizable functional group and a carbon-nitrogen bond as the component (A). The “high molecular weight compound” means a compound having a weight average molecular weight (Mw) of 2,500 or more. Note that, in the present specification, the value of weight average molecular weight (Mw) is a value determined from standard polystyrene conversion using tetrahydrofuran (THF) by a gel permeation chromatography (GPC) method.

Examples of the photopolymerizable functional group contained in the component (A) include ethylenically unsaturated groups such as a (meth)acryloyl group; and an alkenyl group such as a vinyl group or an allyl group. From the viewpoint of improving pattern formability, the component (A) may include a high molecular weight compound having a (meth)acryloyl group as the photopolymerizable functional group, and further, may include a high molecular weight compound having a urethane bond as the carbon-nitrogen bond. Examples of the high molecular weight compound having a (meth)acryloyl group include (meth)acrylate, and examples of the high molecular weight compound having a urethane bond as the carbon-nitrogen bond include (meth)acrylate having a urethane bond (hereinafter, referred to as “urethane (meth)acrylate” in some cases).

The component (A) has at least one of these photopolymerizable functional groups and at least one carbon-nitrogen bond. Furthermore, the total number of photopolymerizable functional groups (the number of functional groups) contained in the high molecular weight compound of the component (A) can be appropriately selected from 2 to 30, 2 to 24, 2 to 20, or 2 to 15 in one molecule from the viewpoint of improving pattern formability and heat resistance, and can be appropriately selected from 6 to 12, 6 to 10, or 6 to 8 from the viewpoint of stabilizing physical properties and characteristics of a cured product to be obtained and reducing tackiness.

Note that, in the present specification, the term “tackiness” means the surface adhesion of a photosensitive layer formed using the photosensitive resin composition (in the case of coating a liquid photosensitive resin composition directly onto a substrate, the surface adhesion of a coating film after coating and drying). When tackiness is high, there is a concern that a production apparatus is easy to contaminate, production may be interrupted in order to clean the apparatus, or defects in the photosensitive layer may occur. Therefore, it is required to reduce tackiness.

Furthermore, the component (A) may include a high molecular weight compound having at least one skeleton selected from the group consisting of a chain hydrocarbon skeleton, an alicyclic skeleton, and an aromatic ring skeleton.

Examples of the urethane (meth)acrylate of the high molecular weight compound include a reaction product obtained by reacting a terminal isocyanate group of a polyadduct of an isocyanate compound having at least two isocyanate groups in one molecule and a diol compound with a (meth)acrylate having a hydroxyl group.

Specific examples of the isocyanate compound having at least two isocyanate groups in one molecule include diisocyanate compounds such as aliphatic diisocyanate compounds such as tetramethylene diisocyanate, hexamethylene diisocyanate, trimethylhexamethylene diisocyanate, decamethylene diisocyanate, and dodecamethylene diisocyanate; alicyclic diisocyanate compounds such as 1,3-bis(isocyanatomethyl)cyclohexane, isophorone diisocyanate, 2,5-bis(isocyanatomethyl)norbornene, bis(4-isocyanatocyclohexyl)methane, 1,2-bis(4-isocyanatocyclohexyl)ethane, 2,2-bis(4-isocyanatocyclohexyl)propane, 2,2-bis(4-isocyanatocyclohexyl)hexafluoropropane, and bicycloheptane triisocyanate; aromatic diisocyanate compounds such as 1,4-phenylene diisocyanate, 2,4-tolylene diisocyanate, 2,6-tolylene diisocyanate, 2,4′-diphenyl methane diisocyanate, 4,4′-diphenyl methane diisocyanate, o-xylylene diisocyanate, m-xylylene diisocyanate, hydrogenated xylylene diisocyanate, and naphthalene-1,5-diisocyanate, and multimers of these diisocyanate compounds such as a uretdione type dimer, an isocyanurate type trimer, or a biuret type trimer. These can be used singly or in combination of two or more types thereof, and two or three isocyanate compounds constituting the multimer may be the same as or different from each other.

Above all, from the viewpoint of improving pattern formability, the isocyanate compound may be appropriately selected from an alicyclic diisocyanate compound and a multimer of the diisocyanate compound, and particularly, may be appropriately selected from isophorone diisocyanate and an isocyanurate type multimer (isocyanurate type polyisocyanate).

The above isocyanate compounds can be used singly or in combination of two or more types thereof.

Furthermore, examples of the diol compound include a diol compound having 1 to 20 carbon atoms, and specific examples thereof include linear or branched saturated diol compounds such as ethylene glycol, diethylene glycol, propanediol, dipropylene glycol, butanediol, pentanediol, isopentyl glycol, hexanediol, nonandiol, decanediol, dodecanediol, dimethyl dodecanediol, and octadecanediol; linear or branched unsaturated diol compounds such as butenediol, pentenediol, hexenediol, methylpentenediol, and dimethylhexenediol; and diol compounds having an alicyclic skeleton such as various cyclohexanediols, various cyclohexane dimethanols, various tricyclodecane dimethanols, hydrogenated bisphenol A and hydrogenated bisphenol F. Herein, the saturated diol compound and the unsaturated diol compound are also collectively referred to as a diol compound having a chain hydrocarbon skeleton.

The above diol compounds can be used singly or in combination of two or more types thereof.

From the viewpoint of improving pattern formability and improving water resistance by increasing the glass transition point (Tg) after polymerization, the diol compound having a chain hydrocarbon skeleton may be appropriately selected from saturated diol compounds having 1 to 20, 2 to 16, or 2 to 14 carbon atoms, and more specifically, may be appropriately selected fromethylene glycol and octadecanediol.

Furthermore, from the viewpoint of improving pattern formability and improving water resistance by increasing the glass transition point (Tg) after polymerization, the diol compound having an alicyclic skeleton may be appropriately selected from diol compounds having an alicyclic skeleton with 5 to 20, 5 to 18, or 6 to 16 carbon atoms, and more specifically, may be appropriately selected from various cyclohexanediols such as 1,3-cyclohexanediol and 1,4-cyclohexanediol or various cyclohexanedimethanols such as 1,3-cyclohexanedimethanol and 1,4-cyclohexanedimethanol.

Examples of the (meth)acrylate having a hydroxyl group include compounds having at least one hydroxyl group and at least one (meth)acryloyl group in one molecule. More specific examples thereof include monofunctional (meth)acrylates such as 2-hydroxyethyl (meth)acrylate, 2-hydroxypropyl (meth)acrylate, 3-chloro-2-hydroxypropyl (meth)acrylate, 2-hydroxybutyl (meth)acrylate, 2-hydroxy-3-phenoxypropyl (meth)acrylate, 2-hydroxy-3-(o-phenylphenoxy)propyl (meth)acrylate, 2-hydroxy-3-(1-naphthoxy)propyl (meth)acrylate, and 2-hydroxy-3-(2-naphthoxy)propyl (meth)acrylate, ethoxylated products thereof, propoxylated products thereof, ethoxylated propoxylated products thereof, and caprolactone-modified products thereof; bifunctional (meth)acrylates such as trimethylolpropane di(meth)acrylate, glycerin di(meth)acrylate, and bis (2-(m eth)acryl oyl oxyethyl)(2-hydroxyethyl)i so cyanurate, ethoxylated products thereof, propoxylated products thereof, ethoxylated propoxylated products thereof, and caprolactone-modified products thereof; bifunctional epoxy (meth)acrylates such as cyclohexane dimethanol type epoxy di(meth)acrylate, tricyclodecane dimethanol type epoxy di(meth)acrylate, hydrogenated bisphenol A type epoxy di(meth)acrylate, hydrogenated bisphenol F type epoxy di(meth)acrylate, hydroquinone type epoxy di(meth)acrylate, resorcinol type epoxy di(meth)acrylate, catechol type epoxy di(meth)acrylate, bisphenol A type epoxy di(meth)acrylate, bisphenol F type epoxy di(meth)acrylate, bisphenol AF type epoxy di(meth)acrylate, biphenol type epoxy di(meth)acrylate, fluorene bisphenol type epoxy di(meth)acrylate, and monoallyl isocyanurate type epoxy di(meth)acrylate; trifunctional or higher (meth)acrylates such as ditrimethylol propane tri(meth)acrylate, pentaerythritol tri(meth)acrylate, dipentaerythritol tetra(meth)acrylate, and dipentaerythritol penta(meth)acrylate, ethoxylated products thereof, propoxylated products thereof, ethoxylated propoxylated products thereof, and caprolactone-modified products thereof; trifunctional or higher epoxy (meth)acrylates such as phenol novolak type epoxy (meth)acrylate, cresol novolak type epoxy poly(meth)acrylate, and isocyanuric acid type epoxy tri(meth)acrylate; and hydroxypropylated products such as trimethylolpropane tri(meth)acrylate and ditrimethylolpropane tetra(meth)acrylate.

These can be used singly or in combination of two or more types thereof.

Herein, the ethoxylated products, propoxylated products, ethoxylated propoxylated products, and hydroxypropylated products of (meth)acrylates are obtained, for example, by using, as raw materials, those obtained by respectively adding one or more of ethylene oxide groups, propylene oxide groups, ethylene oxide groups and propylene oxide groups, and hydroxypropyl groups to alcohol compounds (or phenol compounds) which are raw materials of the (meth)acrylate.

Furthermore, the caprolactone-modified product is obtained, for example, by using, as a raw material, an alcohol compound (or a phenol compound), which is a raw material of the (meth)acrylate, modified with ε-caprolactone.

Examples of the reaction product obtained by reacting a terminal isocyanate group of a polyadduct of an isocyanate compound having at least two isocyanate groups in one molecule and a diol compound with a (meth)acrylate having a hydroxyl group include those having a structural unit represented by General Formula (1) below.

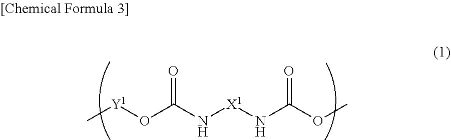

In General Formula (1), X¹ represents a divalent organic group having a chain hydrocarbon skeleton, an alicyclic skeleton, or an aromatic ring skeleton, and Y¹ represents a divalent organic group having a chain hydrocarbon skeleton or an alicyclic skeleton. Furthermore, in a case where the component (A) has a plurality of the structural units, a plurality of X¹'s and Y¹'s may be the same as or different from each other. That is, examples of the component (A) include those having at least one skeleton selected from the group consisting of a chain hydrocarbon skeleton, an alicyclic skeleton, and an aromatic ring skeleton.

Examples of the divalent organic group for X¹ include organic groups derived from an aliphatic diisocyanate compound, an alicyclic diisocyanate compound, and an aromatic diisocyanate compound, that is, divalent organic groups having a chain hydrocarbon skeleton, an alicyclic skeleton, or an aromatic ring skeleton that are residues obtained by removing an isocyanate group from the above-described isocyanate compound, which are exemplified as the compound having an isocyanate group described above. Furthermore, as the divalent organic group represented by X¹, these residues may be used directly, and residues derived from isocyanate compound derivatives such as polyadducts of the isocyanate compound and the diol compound described above may be used.

From the viewpoint of improving pattern formability, and further, improving the transparency, the water resistance, and the moisture resistance of the resin composition at a well-balanced manner, X¹ may be a divalent organic group having an alicyclic skeleton, particularly, a divalent organic group having an alicyclic skeleton that is a residue of isophorone diisocyanate represented by Formula (2) below.

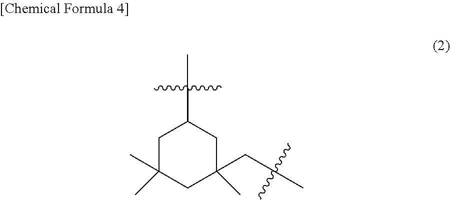 [SMILES: *CC1(C)CC(*)CC(C)(C)C1]

Examples of the divalent organic group having a chain hydrocarbon skeleton or an alicyclic skeleton for Y¹ include organic groups derived from a diol compound having a chain hydrocarbon skeleton and a diol compound having an alicyclic skeleton, that is, divalent organic groups having a chain hydrocarbon skeleton or an alicyclic skeleton that are residues obtained by removing a hydroxyl group from the above-described diol compound, which are exemplified as the diol compound described above.

Particularly, from the viewpoint of improving pattern formability, and further, improving water resistance by increasing the glass transition point (Tg) after polymerization, the divalent organic group having a chain hydrocarbon skeleton may be appropriately selected from residues obtained by removing a hydroxyl group from a saturated diol compound having 1 to 20, 2 to 16, or 2 to 14 carbon atoms, and more specifically, may be appropriately selected from residues obtained by removing a hydroxyl group fromethylene glycol or octadecanediol. Furthermore, from the same viewpoints as described above, the divalent organic group having an alicyclic skeleton may be appropriately selected from residues obtained by removing a hydroxyl group from a diol compound having an alicyclic skeleton with 5 to 20, 5 to 18, or 6 to 16 carbon atoms, and more specifically, may be appropriately selected from residues obtained by removing a hydroxyl group from various cyclohexanediols such as 1,3-cyclohexanediol and 1,4-cyclohexanediol or various cyclohexanedimethanols such as 1,3-cyclohexanedimethanol and 1,4-cyclohexanedimethanol.

Specific examples of the reaction product obtained by reacting a terminal isocyanate group of a polyadduct of an isocyanate compound having at least two isocyanate groups in one molecule and a diol compound with a (meth)acrylate having a hydroxyl group include compounds represented by General Formulas (3) and (4) below.

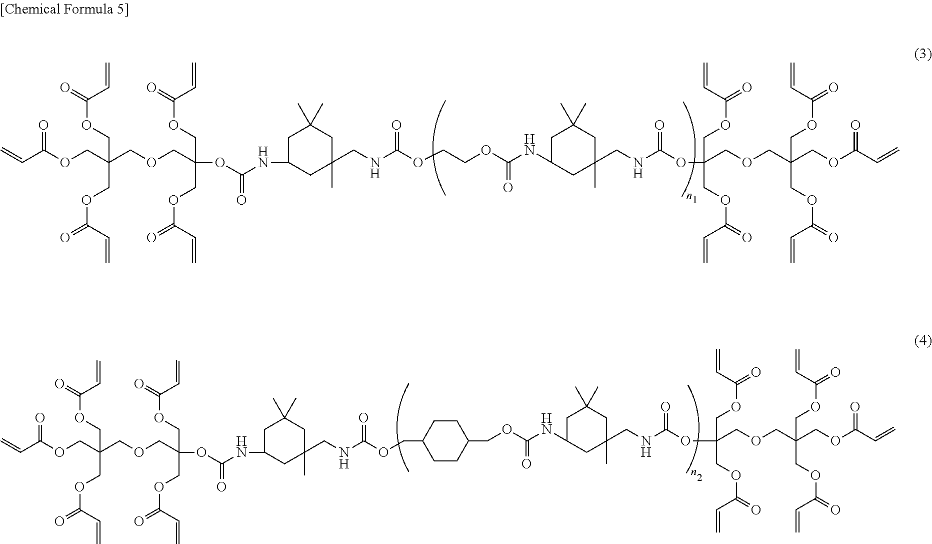

In General Formulas (3) and (4), ni and n2 each independently represents an integer of 3 to 20.

Furthermore, examples of a reaction product in the case of using an isocyanurate type trimer (isocyanurate type triisocyanate), which is a trimer of diisocyanate, as the isocyanate compound, include compounds represented by General Formulas (5) and (6) below.

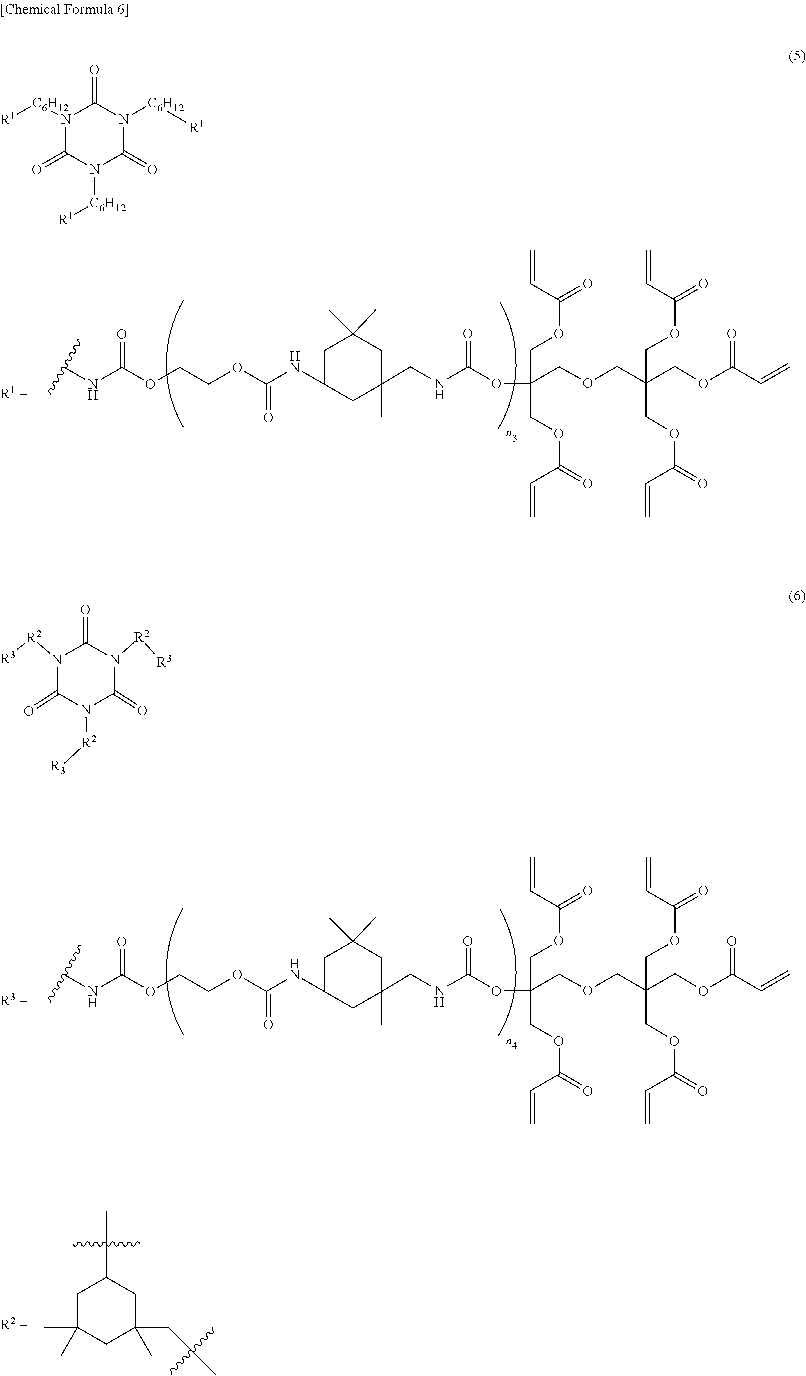

In General Formulas (5) and (6), n3 and n4 each independently represents an integer of 2 to 20.

Examples of commercially available products containing a urethane acrylate represented by General Formula (1) or (3) above include UN-952 (number of functional groups: 10, Mw: 6500 to 11000), UN-953 (number of functional groups: 20, Mw: 14000 to 40000), UN-954 (number of functional groups: 6, Mw: 4500), H-219 (number of functional groups: 9, Mw: 25000 to 50000) (all of them being trade names, manufactured by Negami Chemical Industrial Co., Ltd.). Furthermore, examples of commercially available products containing a urethane acrylate represented by General Formula (6) include UN-905 (number of functional groups: 15, Mw: 40000 to 200000) (trade name, manufactured by Negami Chemical Industrial Co., Ltd.).

Among these, from the viewpoint of pattern formability and photosensitivity, UN-952 and UN-954 are preferred and UN-954 is more preferred.

Note that, in the above description, the number of functional groups and Mw in parentheses are total number of (meth)acryloyl groups contained in the urethane (meth)acrylate and the weight average molecular weight, respectively.

The total number of (meth)acryloyl groups (the number of photopolymerizable functional groups) contained in the urethane (meth)acrylate of the high molecular weight compound may be appropriately selected from 2 to 30, 2 to 24, 2 to 20, or 2 to 15 in one molecule from the viewpoint of improving pattern formability and heat resistance, and may be appropriately selected from 6 to 12, 6 to 10, or 6 to 8 from the viewpoint of stabilizing physical properties and characteristics of a cured product to be obtained and reducing tackiness.

When the number of photopolymerizable functional groups is 6 or more, heat resistance and the rigidity of the cured product at a high temperature can be improved as well as pattern formability. On the other hand, when the number of photopolymerizable functional groups is 30 or less, the rigidity of the cured product is improved, and adhesion with a substrate or the like is improved. Furthermore, a resin composition having an appropriate viscosity can be obtained, coating properties are improved, and in the case of subjecting the resin composition after coating to light irradiation, it is possible to suppress phenomena that only the surface part is likely to be rapidly photocured and the photocuring of the inside does not sufficiently proceed, and excellent resolution is obtainable, so that excellent pattern formability is obtainable even in the case of forming a thick photosensitive layer. Further, after at least one curing of photocuring and thermosetting is performed, the residue of the unreacted (meth)acryloyl group can be further reduced, and fluctuation in physical properties and characteristics of a cured product to be obtained can be further suppressed.

The weight average molecular weight of the component (A) is 2,500 or more, may be 3,000 or more from the viewpoint of improving the coating properties of the resin composition and the resolution, and may be 3,500 or more from the viewpoint of further improving developability and compatibility. On the other hand, the upper limit value of the weight average molecular weight may be 100,000 or less or 50,000 or less from the viewpoint of improving the coating properties of the resin composition and the resolution, and may be 40,000 or less or 20,000 or less from the viewpoint of further improving developability and compatibility.

When the weight average molecular weight is 2,500 or more, dripping of the coated composition can be suppressed when the composition is coated onto the substrate, and thus excellent film formability is obtainable. Furthermore, it is easy to form a thick photosensitive layer and it is also possible to suppress a problem in that a stress of the resin is increased by cure shrinkage to degrade reliability.

On the other hand, when the weight average molecular weight is 100,000 or less, coating properties are improved, a thick photosensitive layer is easily formed, and pattern formability is improved. Furthermore, since solubility with respect to a developer is also excellent, excellent resolution can be exhibited. Further, the transparency of a cured product is improved, and a cured product having excellent transmissivity required as a transparent material can be obtained.

As described above, an aspect of the present embodiment may be a photosensitive resin composition containing, as the component (A), a high molecular weight compound having six to thirty ethylenically unsaturated groups as the photopolymerizable functional group and having a weight average molecular weight of 2,500 to 100,000. Furthermore, an aspect of the present embodiment may be a photosensitive resin composition containing, as the component (A), a high molecular weight compound having six to eight ethylenically unsaturated groups as the photopolymerizable functional group and having a weight average molecular weight of 2,500 to 50,000.

The content of the component (A) may be appropriately selected from 10% by mass or more, 20% by mass or more, or 30% by mass or more, based on the total amount of solid contents of the photosensitive resin composition. When the content is 10% by mass or more, coating properties are improved, and excellent pattern formability is obtainable even in the case of forming a thick photosensitive layer.

Considering pattern formability and coating properties of the resin composition to be obtained and physical properties and characteristics required for a cured product of the resin composition, the upper limit value of the content of the component (A) may be appropriately selected from 95% by mass or less, 85% by mass or less, or 75% by mass or less, based on the total amount of solid contents of the photosensitive resin composition.

Furthermore, the content of urethane (meth)acrylate of the high molecular weight compound in the component (A) may be appropriately selected from 70 to 100% by mass, 80 to 100% by mass, 90 to 100% by mass, 95 to 100% by mass, or 100% by mass (total amount), based on the total amount of solid contents of the component (A), from the viewpoint of improving pattern formability.

<Component (B): low molecular weight compound>

The photosensitive resin composition of the present embodiment contains a low molecular weight compound having a photopolymerizable functional group as the component (B). The “low molecular weight compound” means a compound having a weight average molecular weight of less than 2,500. Herein, even in a case where the low molecular weight compound having a photopolymerizable functional group has a silicon atom, this low molecular weight compound is not classified as a silane compound of a component (F) described below but is classified as the component (B) in priority to the low molecular weight compound having a photopolymerizable functional group.

Examples of the photopolymerizable functional group contained in the component (B) include ethylenically unsaturated groups such as a (meth)acryloyl group; and an alkenyl group such as a vinyl group or an allyl group. The component (B) may be a low molecular weight compound having at least one photopolymerizable functional group, and from the viewpoint of improving pattern formability, the component (B) may have a (meth)acryloyl group as the photopolymerizable functional group. From the viewpoint of improving pattern formability, the component (B) may have two or more photopolymerizable functional groups and may have two to five photopolymerizable functional groups.

The photosensitive resin composition of the present embodiment preferably contains, as the component (B), at least one selected from the group consisting of a component (B1) which is a low molecular weight compound having an isocyanuric ring, a component (B2) which is a low molecular weight compound having a urethane bond, and a component (B3) which is a low molecular weight compound having an alicyclic skeleton. When the photosensitive resin composition of the present embodiment contains at least one of these, there is a tendency that adhesion with a substrate or the like of an electronic component is improved and excellent pattern formability is obtainable. Note that, in the case of a low molecular weight compound having two or more of an isocyanuric ring, a urethane bond, and an alicyclic skeleton, when a low molecular weight compound has at least an isocyanuric ring, the low molecular weight compound is classified as the component (B1), and in a case where a low molecular weight compound has a urethane bond and an alicyclic skeleton, the low molecular weight compound is classified as the component (B2) in priority to the low molecular weight compound having a urethane bond. That is, a low molecular weight compound not having an isocyanuric ring and a urethane bond and having an alicyclic skeleton is classified as the component (B3).

(Component (B1): low molecular weight compound having isocyanuric ring)

From the viewpoint of improving pattern formability, the component (B1) may have two or more photopolymerizable functional groups, may have two to five photopolymerizable functional groups, may have two or three photopolymerizable functional groups, and may have three photopolymerizable functional groups.

The photopolymerizable functional group, which the component (B1) has, has been described as the photopolymerizable functional group contained in the component (B) mentioned above, and from the viewpoint of improving pattern formability, the component (B1) may have a (meth)acryloyl group as the photopolymerizable functional group.

Examples of the component (B1) include a compound represented by General Formula (7) below.

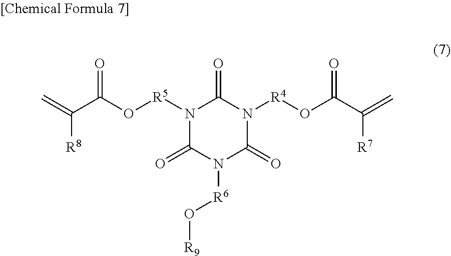

(In General Formula (7), R⁴, R⁵, and R⁶ each independently represents an alkylene group having 1 to 6 carbon atoms, R⁷ and R⁸ each independently represents a hydrogen atom or a methyl group, and R⁹ represents a hydrogen atom or a (meth)acryloyl group.)

In General Formula (7), the alkylene group having 1 to 6 carbon atoms represented by R⁴, R⁵, and R⁶ may be an alkylene group having 1 to 4 carbon atoms, and may be an alkylene group having 1 to 3 carbon atoms.

Examples of the alkylene group having 1 to 6 carbon atoms include a methylene group, an ethylene group, a propylene group, a butylene group, an isopropylene group, an isobutylene group, a t-butylene group, a pentylene group, and a hexylene group, and among these, from the viewpoint of improving pattern formability, the alkylene group having 1 to 6 carbon atoms may be an ethylene group.

In General Formula (7), R⁷ and R⁸ each independently represents a hydrogen atom or a methyl group, and may be a hydrogen atom from the viewpoint of improving pattern formability.

In General Formula (7), R⁹ represents a hydrogen atom or a (meth)acryloyl group, and may be a (meth)acryloyl group from the viewpoint of improving pattern formability.

The compound represented by General Formula (7) may be one or more selected from the group consisting of a compound represented by General Formula (7-1) below and a compound represented by General

Formula (7-2) below, and may be a compound represented by General Formula (7-1) below from the viewpoint of improving pattern formability.

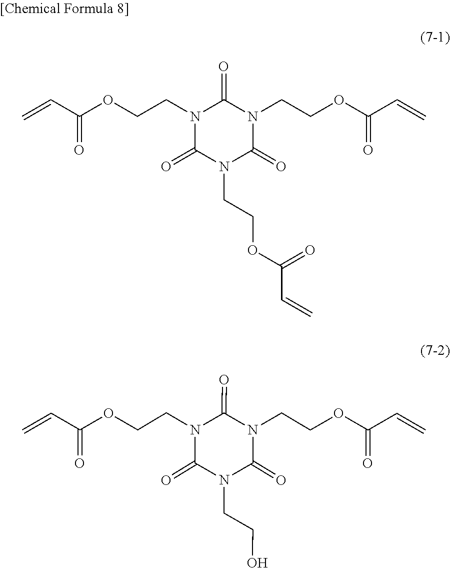

The weight average molecular weight of the component (B1) is less than 2,500, and may be appropriately selected from 200 to 1,500, 300 to 1,000, or 350 to 600 from the viewpoint of improving pattern formability.

Commercially available products may be used as the component (B1). Examples of the commercially available products include “A-9300” manufactured by SHIN-NAKAMURA CHEMICAL Co., Ltd. (the compound represented by Formula (7-1) above) and “M-215” manufactured by TOAGOSEI CO., LTD. (the compound represented by Formula (7-2) above).

The component (B1) can be used singly or in combination of two or more types thereof.

(Component (B2): low molecular weight compound having urethane bond)

From the viewpoint of improving pattern formability, the component (B2) may have two or more photopolymerizable functional groups, may have two to six photopolymerizable functional groups, may have two to four photopolymerizable functional groups, and may have two photopolymerizable functional groups.

The photopolymerizable functional group, which the component (B2) has, has been described as the photopolymerizable functional group contained in the component (B) mentioned above, and from the viewpoint of improving pattern formability, the component (B2) may have a (meth)acryloyl group as the photopolymerizable functional group.

In the present specification, the component (B2) having a (meth)acryloyl group as the photopolymerizable functional group is simply referred to as “urethane (meth)acrylate of the low molecular weight compound” in some cases.

Examples of the urethane (meth)acrylate of the low molecular weight compound include a reaction product of a (meth)acrylate having a hydroxyl group and an isocyanate compound having an isocyanate group. Herein, examples of the (meth)acrylate having a hydroxyl group and the isocyanate compound include the acrylate having a hydroxyl group and the isocyanate compound which are exemplified as raw materials used in generation of the high molecular weight compound described in the description of the component (A). Note that, regarding the isocyanate compound, in addition to the compounds described above, a monoisocyanate compound can also be used. Examples of the monoisocyanate compound include aliphatic monoisocyanate compounds such as ethyl isocyanate, propyl isocyanate, butyl isocyanate, octadecyl isocyanate, and 2-isocyanate ethyl (meth)acrylate; alicyclic monoisocyanate compounds such as cyclohexyl isocyanate; and aromatic monoisocyanate compounds such as phenyl isocyanate.

Herein, as those which are appropriately selected from the viewpoint of improvement in pattern formability or the like, the same ones which are appropriately selected as those used in generation of the high molecular weight compound from the same viewpoint are exemplified.

Furthermore, examples of the urethane (meth)acrylate of the low molecular weight compound include a reaction product obtained by reacting a terminal isocyanate group of a polyadduct of an isocyanate compound having at least two isocyanate groups in one molecule and a diol compound with a (meth)acrylate having a hydroxyl group. Herein, examples of the isocyanate compound having at least two isocyanate groups in one molecule, the diol compound, and the (meth)acrylate having a hydroxyl group each include the isocyanate compound having at least two isocyanate groups in one molecule, the diol compound, and the (meth)acrylate having a hydroxyl group which are exemplified as those used in generation of the high molecular weight compound. Herein, as those which are appropriately selected from the viewpoint of improvement in pattern formability or the like, the same ones which are appropriately selected as those used in generation of the high molecular weight compound from the same viewpoint are exemplified.

Examples of this reaction product include those having a structural unit represented by General Formula (8) below.

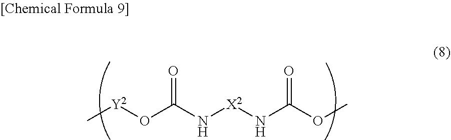

In General Formula (8), X² represents a divalent organic group having a chain hydrocarbon skeleton, an alicyclic skeleton, or an aromatic ring skeleton, and Y² represents a divalent organic group having a chain hydrocarbon skeleton or an alicyclic skeleton. That is, examples of the component (B2) include those having at least one skeleton selected from the group consisting of a chain hydrocarbon skeleton, an alicyclic skeleton, and an aromatic ring skeleton. As X² and Y², those which are the same as X¹ and Y¹ in General Formula (1) are exemplified, respectively.

From the viewpoint of improving pattern formability, and further, improving the transparency, the water resistance, and the moisture resistance of the resin composition at a well-balanced manner, X² may be appropriately selected from a divalent organic group having a chain hydrocarbon skeleton, a divalent organic group having a branched chain hydrocarbon skeleton, and a branched alkylene group having 2 to 12 carbon atoms, for example, residues of the aliphatic diisocyanate compound described above. Furthermore, from the same viewpoint, Y² may be appropriately selected from a divalent organic group having an alicyclic skeleton, for example, residues of the diol compound having an alicyclic skeleton described above.

Specific examples of the urethane (meth)acrylate of the low molecular weight compound include urethane acrylates represented by General Formula (9) below.

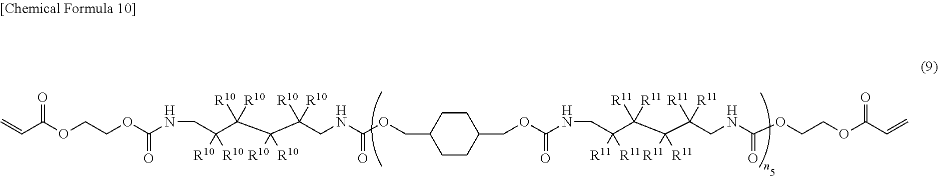

In General Formula (9) above, ns represents an integer of 1 to 4. R¹⁰ and R¹¹ each independently are a hydrogen atom or an alkyl group having 1 to 4 carbon atoms, and at least three of each of a plurality of R¹⁰'s and R¹¹'s are an alkyl group having 1 to 4 carbon atoms.

Of the urethane acrylates represented by General Formula (9) above, examples of commercially available products, which contain a urethane acrylate having structural units in which X² in General Formula (8) above is a residue of trimethyl hexamethylene diisocyanate that is a divalent organic group having a chain hydrocarbon skeleton and Y² is a residue of cyclohexanedimethanol of the divalent organic group having an alicyclic skeleton, include TMCH-5R (trade name, number of functional groups: 2, Mw: 950, manufactured by Hitachi Chemical Co., Ltd.).

Furthermore, examples of commercially available products containing a urethane (meth)acrylate having a structural unit represented by General Formula (8) above include KRM8452 (number of functional groups: 10, Mw: 1200, manufactured by DAICEL-ALLNEX LTD.), UN-3320HA (number of functional groups: 6, Mw: 1500, manufactured by Negami Chemical Industrial Co., Ltd.), UN-3320HC (number of functional groups: 6, Mw: 1500, manufactured by Negami Chemical Industrial Co., Ltd.). Note that, in the above description, the number of functional groups and Mw in parentheses are total number of (meth)acryloyl groups contained in the urethane (meth)acrylate and the weight average molecular weight, respectively.

The weight average molecular weight of the component (B2) is less than 2,500, may be 2,000 or less from the viewpoint of improving adhesion, and may be 1,500 or less or 1,000 or less from the viewpoint of further improving resolution. On the other hand, the lower limit value of the weight average molecular weight may be appropriately used according to the desired purpose, and may be 500 or more or 700 or more from the viewpoint of film formability.

By containing the component (B2) as the component (B), the effect of improving pattern formability is increased.

(Component (B3): low molecular weight compound having alicyclic skeleton)

From the viewpoint of improving pattern formability, the component (B3) may have two or more photopolymerizable functional groups, may have two to four photopolymerizable functional groups, and may have two photopolymerizable functional groups.

The photopolymerizable functional group, which the component (B3) has, has been described as the photopolymerizable functional group contained in the component (B) mentioned above, and from the viewpoint of improving pattern formability, the component (B3) may have a (meth)acryloyl group as the photopolymerizable functional group.

The alicyclic skeleton, which the component (B3) has, is not particularly limited, and examples thereof include an alicyclic hydrocarbon skeleton having 5 to 20 carbon atoms. The alicyclic hydrocarbon skeleton may be at least one selected from the group consisting of a cyclopentane skeleton, a cyclohexane skeleton, a cyclooctane skeleton, a cyclodecane skeleton, a norbornane skeleton, a dicyclopentane skeleton, and a tricyclodecane skeleton. Among these, from the viewpoint of improving pattern formability, the alicyclic hydrocarbon skeleton may be a tricyclodecane skeleton.

The weight average molecular weight of the component (B3) is less than 2,500, may be 2,000 or less from the viewpoint of improving adhesion, and may be 1,500 or less, 1,000 or less, or 500 or less from the viewpoint of further improving resolution. On the other hand, the lower limit value of the weight average molecular weight may be appropriately used according to the desired purpose, and may be 150 or more or 200 or more from the viewpoint of film formability.

The component (B3) may be tricyclodecane dimethanol diacrylate from the viewpoint of pattern formability.

Commercially available products may be used as the component (B3). Examples of the commercially available products include A-DCP (tricyclodecane dimethanol diacrylate, manufactured by SHIN-NAKAMURA CHEMICAL Co., Ltd.).

The content (total content) of the component (B) may be appropriately selected from 5% by mass or more, 10% by mass or more, 20% by mass or more, or 30% by mass or more, based on the total amount of solid contents of the photosensitive resin composition. When the content of the component (B) is 5% by mass or more, excellent pattern formability is obtainable even in the case of forming a thick photosensitive layer, and excellent rigidity of the cured product is also obtainable. From the same viewpoint as described above, the upper limit value of the content of the component (B) may be appropriately selected from 70% by mass or less, 60% by mass or less, or 50% by mass or less, based on the total amount of solid contents of the photosensitive resin composition.

The content of the component (B) may be appropriately selected from 20 to 120 parts by mass, 25 to 100 parts by mass, 30 to 80 parts by mass, or 40 to 80 parts by mass, based on 100 parts by mass of the total amount of solid contents of the component (A) and the component (E) (provided that, only the component (A) in a case where the component (E) is not contained), from the viewpoint of improving pattern formability and the rigidity of the cured product.

The total content of the components (B1) to (B3) in the component (B) may be appropriately selected from 50% by mass or more, 70% by mass or more, 80% by mass or more, 90% by mass or more, 95% by mass or more, or practically 100% by mass.

In the case of using at least two or more of the components (B1) to (B3), the content of the component (B2) in the total amount of solid contents of the component (B) may be appropriately selected from 10% by mass or more, 15% by mass or more, or 20% by mass or more. When the content of the component (B2) is 10% by mass or more, excellent pattern formability is obtainable even in the case of forming a thick photosensitive layer, and excellent rigidity of the cured product is also obtainable. From the same viewpoint as described above, the upper limit value of the component (B2) may be appropriately selected from 90% by mass or less, 80% by mass or less, or 70% by mass or less.

<Component (C): photopolymerization initiator>

The photosensitive resin composition of the present embodiment contains a photopolymerization initiator as the component (C). The component (C) is not particularly limited as long as it can polymerize at least one of the component (A) and the component (B), and can be appropriately selected from photopolymerization initiators that are generally used. From the viewpoint of pattern formability, examples thereof include those which generate a free radical by an active ray such as acyl phosphine oxide-based, oxime ester-based, aromatic ketone-based, quinone-based, alkylphenone-based, imidazole-based, acridine-based, phenylglycine-based, and coumarin-based photopolymerization initiators.

The acyl phosphine oxide-based photopolymerization initiator is a photopolymerization initiator having an acyl phosphine oxide group [>P(═O)—C(═O)—R], and examples thereof include (2,6-dimethoxybenzoyl)-2,4 ,6-pentylphosphine oxide, bis(2,4,6-trimethylbenzoyl)-phenylphosphine oxide, 2,4,6-trimethylbenzoyl diphenylphosphine oxide (“IRGACURE-TPO” (manufactured by BASF)), ethyl-2,4,6-trimethylbenzoyl phenylphosphinate, bis (2,4,6-trimethylbenzoyl)-phenylphosphine oxide (“IRGACURE-819” (manufactured by BASF)), (2,5-dihydroxyphenyl)diphenylphosphine oxide, (p-hydroxyphenyl)diphenylphosphine oxide, bis(p-hydroxyphenyl)phenylphosphine oxide, and tris(p-hydroxyphenyl)phosphine oxide.

The oxime ester-based photopolymerization initiator is a photopolymerization initiator having an oxime ester bond, and examples thereof include 1,2-octanedione-1-[4-(phenylthio)phenyl]-2-(O-benzoyloxime) (trade name: OXE-01, manufactured by BASF), 1- [9-ethyl-6-(2-methylbenzoyl)-9H-carbazole-3-yl]ethanone 1-(O-acetyloxime) (trade name: OXE-02, manufactured by BASF), 1-phenyl-1,2-propanedione-2-[O-(ethoxycarbonyl)oxime] (trade name: Quantacure-PDO, manufactured by Nippon Kayaku Co., Ltd.).

Examples of the aromatic ketone-based photopolymerization initiator include benzophenone, N,N,N′,N′-tetramethyl-4,4′-diaminobenzophenone (Michler's ketone), N,N,N′,N′-tetraethyl-4,4′-diaminobenzophenone, 4-methoxy-4′-dimethylaminobenzophenone, 2,2-dimethoxy-1,2- diphenylethane-1- one (“IRGACURE-651” (manufactured by BASF)), 2-benzyl-2- dimethyl amino-1-(4-morpholinophenyl)-butane-1-one (“IRGACURE-369 ” (manufactured by BASF)), and 2-methyl-1- [4-(methylthio)phenyl]-2-morpholino-propan-1-one (“IRGACURE-907” (manufactured by BASF)).

Examples of the quinone-based photopolymerization initiator include 2-ethylanthraquinone, phenanthrenequinone, 2-t-butylanthraquinone, octamethylanthraquinone, 1,2-benzanthraquinone, 2,3-b enzanthraquinone, 2-phenylanthraquinone, 2,3-diphenylanthraquinone, 1-chloroanthraquinone, 2-methylanthraquinone, 1,4-naphthoquinone, 9 ,10-phenanthraquinone, 2-methyl-1,4-naphthoquinone, and 2,3-dimethylanthraquinone.

Examples of the alkylphenone-based photopolymerization initiator include benzoin-based compounds such as benzoin, benzoin methyl ether, benzoin ethyl ether, benzoin isopropyl ether, and benzoin phenyl ether, 2,2- dimethoxy-1,2-diphenylethane-1-one (“IRGACURE-651” (manufactured by BASF)), 1-hydroxy-cyclohexyl-phenyl-ketone (“IRGACURE-184” (manufactured by BASF)), 2-hydroxy-2-methyl-1-phenyl-propan-1-one (“IRGACURE-1173” (manufactured by BASF)), 1-[4-(2-hydroxyethoxy)-phenyl]-2-hydroxy-2-methyl-1-propan-1-one (“IRGACURE-2959” (manufactured by BASF)), and 2-hydroxy-1-{4-[4-(2-hydroxy-2-methyl-propionyl)-benzyl]phenyl}-2-methyl-propan-1-one (“IRGACURE-127” (manufactured by BASF)).

Examples of the imidazole-based photopolymerization initiator include, as 2,4,5-triarylimidazole dimers, 2-(o-chlorophenyl)-4,5-diphenylimidazole dimer such as 2-(2-chlorophenyl)-1-[2-(2-chlorophenyl)-4,5-diphenyl-1,3-diazole-2-yl]-4,5-diphenyl imidazole, 2-(o-chlorophenyl)-4,5-di(methoxyphenyl)imidayole dimer, 2-(o-fluorophenyl)-4,5-diphenylimidazole dimer, 2-(o-methoxyphenyl)-4,5-diphenylimidazole dimer, and 2-(p-methoxyphenyl)-4,5-diphenylimidazole dimer.

Examples of the acridine-based photopolymerization initiator include 9-phenylacridine and 1,7-bis(9,9′-acridinyl)heptane.

Examples of the phenylglycine-based photopolymerization initiator include N-phenylglycine, N-methyl-N-phenylglycine, and N-ethyl-N-phenylglycine.

Furthermore, examples of the coumarin-based photopolymerization initiator include 7-amino-4-methylcoumarin, 7-dimethylamino-4-methylcoumarin, 7-diethylamino-4-methylcoumarin, 7-methylamino-4-methylcoumarin, 7-ethylamino-4-methylcoumarin, 7-dimethylamino cyclopenta[c]coumarin, 7-aminocyclopenta[c]coumarin, 7-diethylaminocyclopenta[c]coumarin, 4,6-dimethyl-7-ethylaminocoumarin, 4,6-diethyl-7-ethylaminocoumarin, 4,6-dimethyl-7-diethylaminocoumarin, 4,6-dimethyl-7-dimethylaminocoumarin, 4,6-diethyl-7-ethylaminocoumarin, 4,6-diethyl-7-dimethylaminocoumarin, 2,3,6,7,10,11-hexanehydro-1H,5H-cyclopenta[3,4] [1 ]benzopyrano-[6,7,8-ij]quinolizine 12(9H)-one, 7-diethylamino-5′,7′-dimethoxy-3,3′-carbonyl biscoumarin, 3,3′-carbonylbis [7-(diethylamino)coumarin], and 7-(diethylamino)-3-(2-thienyl)coumarin.

Among these (C) photopolymerization initiators, from the viewpoint of improving pattern formability, a compound represented by General Formula (C1) below or a compound represented by General Formula (C2) below may be used.

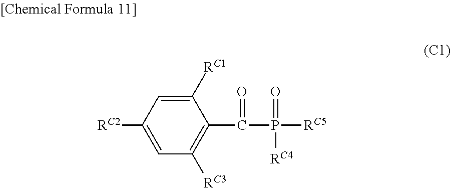

(R^{C1}, R^{C2}, and R^{C3} each independently represents a hydrogen atom, an alkyl group having 1 to 6 carbon atoms, or an alkoxy group having 1 to 6 carbon atoms; and R^{C4} and R^{C5} each independently represents a hydrogen atom, an alkyl group having 1 to 6 carbon atoms, an alkoxy group having 1 to 6 carbon atoms, or an aryl group having 6 to 12 carbon atoms; and each of R^{C1} to R^{C5} other than the hydrogen atom may have a substituent.)

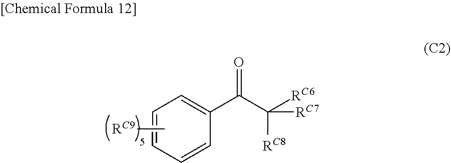

(R^{C6} represents a hydroxyl group, an alkoxy group having 1 to 6 carbon atoms, or an amino group; R^{C7} and R^{C8} each independently represents a hydrogen atom, an alkyl group having 1 to 8 carbon atoms, an aryl group having 6 to 12 carbon atoms, or an alkoxy group having 1 to 8 carbon atoms, R^{C7} and R^{C8} may be bonded to each other to form a cyclic structure having 3 to 16 carbon atoms; each of R^{C6} to R^{C8} other than the hydroxyl group and the hydrogen atom may have a substituent, in an amino group having a substituent, substituents may be bonded to each other to form a cyclic structure having 3 to 12 carbon atoms; and R^{C9}'s each independently represents a hydrogen atom, a halogen atom, a hydroxyl group, an amino group, a mercapto group, or an organic group having 1 to 10 carbon atoms which may contain one or more atoms selected from an oxygen atom, a nitrogen atom, and a sulfur atom.)

In General Formula (C1), R^{C1}, R^{C2}, and R^{C3} each independently represents a hydrogen atom, an alkyl group having 1 to 6 carbon atoms, or an alkoxy group having 1 to 6 carbon atoms.

The alkyl group having 1 to 6 carbon atoms represented by R^{C1}, R^{C2}, and R^{C3} may be an alkyl group having 1 to 3 carbon atoms and may be an alkyl group having 1 or 2 carbon atoms. Examples of the alkyl group include a methyl group, an ethyl group, a propyl group, an isopropyl group, a n-butyl group, a tert-butyl group, a n-heptyl group, and a n-hexyl group.

The alkoxy group having 1 to 6 carbon atoms represented by R^{C1}, R^{C2}, and R^{C3} may be an alkoxy group having 1 to 3 carbon atoms and may be an alkoxy group having 1 or 2 carbon atoms. Examples of the alkoxy group include a methoxy group, an ethoxy group, a propyloxy group, an isopropyloxy group, a n-butoxy group, and a tert-butoxy group.

Among these groups, R^{C1}, R^{C2}, and R^{C3} may be a methyl group from the viewpoint of improving pattern formability.

In General Formula (C1), R^{C4} and R^{C5} each independently represents a hydrogen atom, an alkyl group having 1 to 6 carbon atoms, an alkoxy group having 1 to 6 carbon atoms, or an aryl group having 6 to 12 carbon atoms.

The alkyl group having 1 to 6 carbon atoms and the alkoxy group having 1 to 6 carbon atoms represented by R^{C4} and R^{C5} will be described in the same manner as in the case of R^{C1}, R^{C2}, and R^{C3}.

The aryl group having 6 to 12 carbon atoms represented by R^{C4} and R^{C5} may be an aryl group having 6 to 10 carbon atoms and may be an aryl group having 6 to 8 carbon atoms. Examples of the aryl group include a phenyl group and a naphthyl group.

Examples of substituents which R^{C1} to R^{C5} may have include a halogen atom, a carboxy group, a hydroxy group, an amino group, a mercapto group, an alkyl group having 1 to 6 carbon atoms, an alkoxy group having 1 to 6 carbon atoms, and an aryl group having 6 to 12 carbon atoms. The alkyl group, the alkoxy group, and the aryl group that are substituents which R^{C1} to R^{C5} may have are the same as the alkyl group, the alkoxy group, and the aryl group described as R^{C1} to R^{C5}.

In General Formula (C2), R^{C6} represents a hydroxyl group, an alkoxy group having 1 to 6 carbon atoms, or an amino group.

The alkoxy group represented by R^{C6} will be described in the same manner as in the case of R^{C1}, R^{C2}, and R^{C3} in General Formula (C1).

Among these groups, R^{C6} may be a hydroxyl group from the viewpoint of improving pattern formability.

In General Formula (C2), R^{C7} and R^{C8} each independently represents a hydrogen atom, an alkyl group having 1 to 8 carbon atoms, an alkoxy group having 1 to 8 carbon atoms, or an aryl group having 6 to 12 carbon atoms.

The alkyl group, the alkoxy group, and the aryl group represented by R^{C7} and R^{C8} are the same as the alkyl group, the alkoxy group, and the aryl group represented by R^{C1} to R^{C5} in General Formula (C1).

R^{C7} and R^{C8} may be bonded to each other to form a cyclic structure having 3 to 16 carbon atoms.

The above-described cyclic structure may be a cyclic structure having 4 to 10 carbon atoms and may be a cyclic structure having 5 to 8 carbon atoms.

The above-described cyclic structure may be an alicyclic structure from the viewpoint of improving pattern formability, and examples of the alicyclic structure include a cyclopentane structure, a cyclohexane structure, a cycloheptane structure, and a cyclooctane structure. Furthermore, these alicyclic structures may contain a carbon atom to which R^{C7} and R^{C8} are directly bonded together.

The substituents which R^{C6} to R^{C8} may have will be described in the same manner as substituents which R^{C1} to R^{C5} in General Formula (C1) above may have.

However, in an amino group having a substituent, substituents may be bonded to each other to form a cyclic structure having 3 to 12 carbon atoms.

The cyclic structure formed by the substituents of the amino group may be a cyclic structure having 3 to 10 carbon atoms and may be a cyclic structure having 3 to 5 carbon atoms.

The above-described cyclic structure may be a 5- to 10-membered ring containing a nitrogen atom of the amino group, may be a 5- to 7-membered ring containing a nitrogen atom of the amino group, and may be a 6-membered ring containing a nitrogen atom of the amino group. Further, these cyclic structures may contain a hetero atom other than the nitrogen atom, such as an oxygen atom. Specific examples of the cyclic structure formed by the substituents of the amino group include a structure represented by Formula (C3) below (morpholino group).

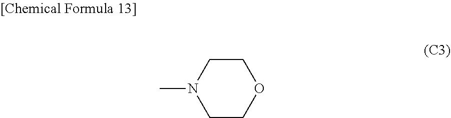

In General Formula (C2), R^{C9}'s each independently represents a hydrogen atom, a halogen atom, a hydroxyl group, an amino group, a mercapto group, or an organic group having 1 to 10 carbon atoms which may contain at least one atom selected from an oxygen atom, a nitrogen atom, and a sulfur atom.

The organic group having 1 to 10 carbon atoms represented by R^{C9} may be an organic group having 1 to 6 carbon atoms and may be an organic group having 1 to 4 carbon atoms.

The organic group having 1 to 10 carbon atoms represented by R^{C9} may be a hydrocarbon group such as an alkyl group, an alkenyl group, or an aryl group. These alkyl group, alkenyl group, and aryl group are the same as the alkyl group, the alkenyl group, and the aryl group represented by R^{C1} to R^{C5} in General Formula (C1).

Examples of the organic group having 1 to 10 carbon atoms that is represented by R^{C9} and contains an oxygen atom include an alkoxy group having 1 to 10 carbon atoms.

Examples of the organic group having 1 to 10 carbon atoms that is represented by R^{C9} and contains a nitrogen atom include a group represented by General Formula (C3) above.

Examples of the organic group having 1 to 10 carbon atoms that is represented by R^{C9} and contains a sulfur atom include an alkylthio group such as a methylthio group.

The content of the component (C) may be appropriately selected from such an amount that the absorbance for light with a wavelength of 365 nm at a thickness (thickness after drying) 50 μm of the photosensitive layer formed by the photosensitive resin composition is 0.35 or less, 0.3 or less, 0.2 or less, or 0.1 or less. With the above content, for example, even in the case of forming a pattern with a thick photosensitive layer having a thickness of 70 μm or more, light is likely to pass through to the bottom of the photosensitive layer (the surface of the photosensitive layer on the substrate side), and thus pattern formability can be improved. Herein, regarding the absorbance, the absorbance for light with a wavelength of 365 nm can be measured using a polyethylene terephthalate film or the like alone as the reference, for example, by using an ultraviolet-visible spectrophotometer (product name: “U-3310 Spectrophotometer”, manufactured by Hitachi High-Tech Corporation).

The content of the component (C) may be appropriately determined by the absorbance at a thickness 50 μm of the photosensitive layer, and generally, may be appropriately selected from 0.05 to 20% by mass, 0.05 to 12% by mass, 0.1 to 8% by mass, 0.1 to 5% by mass, or 0.1 to 3% by mass, based on the total amount of solid contents of the photosensitive resin composition. With the above content, the sensitivity of the photosensitive resin composition can be improved to suppress deterioration of the resist shape, and pattern formability can be improved.

Furthermore, in addition to the above-described component (C), (C′) a photopolymerization initiation assistant such as tertiary amines such as N,N-dimethylaminobenzoic acid ethyl ester, N,N-dimethylaminobenzoic acid isoamyl ester, pentyl-4-dimethylaminobenzoate, triethylamine, and triethanolamine can also be used singly or in combination of two or more types thereof.

<Component (D): triazole-based compound>

The photosensitive resin composition of the present embodiment contains a triazole-based compound as the component (D). The triazole-based compound is a compound having a triazole skeleton. The triazole-based compound is excellent in adhesion with the copper surface, can be easily removed by development, and does not impair the curability of the photosensitive resin composition. Therefore, even in the case of forming a thick photosensitive layer on the copper surface and forming a resist pattern with a fine line width and a narrow line space, excellent pattern formability can be realized. Furthermore, in the case of a high radical concentration in the reaction system such as the condition of a high exposure amount, it is considered that the hydrogen of the triazole-based compound is extracted to play a role as a polymerization inhibitor, and the process margin is widened, so that excellent pattern formability can be realized under the same exposure conditions in both of a substrate having a copper surface and a substrate not having a copper surface. Further, the triazole-based compound has higher solubility in a solvent and is easier to handle than tetrazole that is one of heterocyclic compounds. In the case of a tetrazole-based compound, there is a possibility that the tetrazole-based compound may be deposited in a storage stability test of the photosensitive resin film in cold storage. Of the triazole-based compound, benzotriazole is more preferred.

Examples of the triazole-based compound include 1,2,3-triazole, 1,2,4-triazole, benzotriazole, and derivatives thereof. More specific examples of the triazole-based compound include 1-methyl-1,2,3-triazole, 1-phenyl-1,2,3-triazole, 4-methyl-2-phenyl-1,2,3-triazole, 1-methyl-1,2,4-triazole, 1,3-diphenyl-1,2,4-triazole, benzotriazole, 1-methylbenzotrinole, 5 ,6-dimethylbenzotrinole, and 2-phenylbenzotriazole. These can also be used singly or in combination of two or more types thereof.

The component (D) preferably includes a benzotriazole-based compound having a benzotriazole skeleton. Since the benzotriazole-based compound is excellent in adhesion with the copper surface, can be easily removed by development, and does not impair the curability of the photosensitive resin composition, even in the case of forming a thick photosensitive layer on the copper surface and forming a resist pattern with a fine line width and a narrow line space, excellent pattern formation tends to be possible by using the benzotriazole-based compound,. Furthermore, from the viewpoint of more sufficiently obtaining the above-described effect, among the benzotriazole-based compounds, benzotriazole is preferred.

The molecular weight of the triazole-based compound is preferably 100 or more and more preferably 150 or more. Furthermore, the molecular weight of the triazole-based compound is preferably 5000 or less and more preferably 2000 or less. When the molecular weight is 100 or more, there is a tendency that the triazole-based compound is difficult to volatilize during coating. On the other hand, when the molecular weight is 5000 or less, there is a tendency that the triazole-based compound is easy to move during a first heating step described below, easy to coordinate to the substrate, and excellent in adhesion with the copper surface, and thus the development residue reduction effect is further improved.

The content of the component (D) in the photosensitive resin composition may be 0.1 to 10% by mass, 1.0 to 8.0% by mass, or 3.0 to 6.0% by mass, based on the total amount of solid contents of the photosensitive resin composition. When the content of the component (D) is 0.1% by mass or more, an effect of reducing development residue tends to be more significantly obtained, and when the content thereof is 10% by mass or less, both of a reduction in development residue and pattern formability under the same exposure amount tend to be easily achieved.

<Component (E): high Tg high molecular weight compound>

The photosensitive resin composition of the present embodiment may contain, as the component (E), a high molecular weight compound having a glass transition temperature of 70° C. to 150° C. and not having a carbon-nitrogen bond. The “high molecular weight compound” is the same as the definition in the above-described component (A). By containing the component (E), the effect of suppressing the tackiness of the photosensitive resin composition is attained.

The component (E) may be a component containing an ethylenically unsaturated group from the viewpoint of pattern formability and the viewpoint of reducing tackiness. Examples of the ethylenically unsaturated group include a (meth)acryloyl group and a vinyl group, and from the viewpoint of pattern formability, the ethylenically unsaturated group may be a (meth)acryloyl group.

The component (E) may include a high molecular weight compound having at least one skeleton selected from the group consisting of an alicyclic skeleton and an aromatic ring skeleton, and may include a high molecular weight compound having an alicyclic skeleton from the viewpoint of pattern formability and the viewpoint of reducing tackiness.

The high molecular weight compound having an alicyclic skeleton can be produced, for example, by reacting a part of an acid group derived from an acid group-containing acrylic resin (e1) not having a carbon-nitrogen bond with an epoxy group derived from an alicyclic epoxy group-containing unsaturated compound (e2) not having a carbon-nitrogen bond.

As the acid group derived from an acid group-containing acrylic resin (e1) not having a carbon-nitrogen bond, a copolymer obtained by copolymerizing an acid having an ethylenically unsaturated group and one or two or more kinds selected from monomers of an ester of (meth)acrylic acid, a vinyl aromatic compound, a polyolefin-based compound, and the like can be used. Specifically, examples thereof include copolymers obtained by using an acid having an ethylenically unsaturated group such as (meth)acrylic acid, 2-carboxyethyl (meth)acrylate, 2-carboxypropyl (meth)acrylate, or maleic acid (anhydride) as an essential component and copolymerizing the acid with one or two or more kinds of monomers selected from monomers of an ester of (meth)acrylic acid such as methyl (meth)acrylate, ethyl (meth)acrylate, propyl (meth)acrylate, butyl (meth)acrylate, 2-ethylhexyl (meth)acrylate, stearyl (meth)acrylate, hydroxyethyl (meth)acrylate, and hydroxypropyl (meth)acrylate; a vinyl aromatic compound such as styrene, α-methylstyrene, vinyltoluene, and p-chlorostyrene; a polyolefin-based compound such as butadiene, isoprene, and chloroprene, and other monomers such as methyl isopropenyl ketone, vinyl acetate, and vinyl propionate.

The acid value of the component (e1) may be 15 mgKOH/g or more and may be 40 to 500 mgKOH/g. When the component (e1) has such an acid value, even after reacting the component (e1) with the component (e2) described below, a sufficient amount of the acid group remains in the component (E).

The alicyclic epoxy group-containing unsaturated compound (e2) not having a carbon-nitrogen bond is preferably a compound having one ethylenically unsaturated group and an alicyclic epoxy group in one molecule. Specifically, for example, compounds represented by any of

Formulas (I) to (X) below are exemplified.

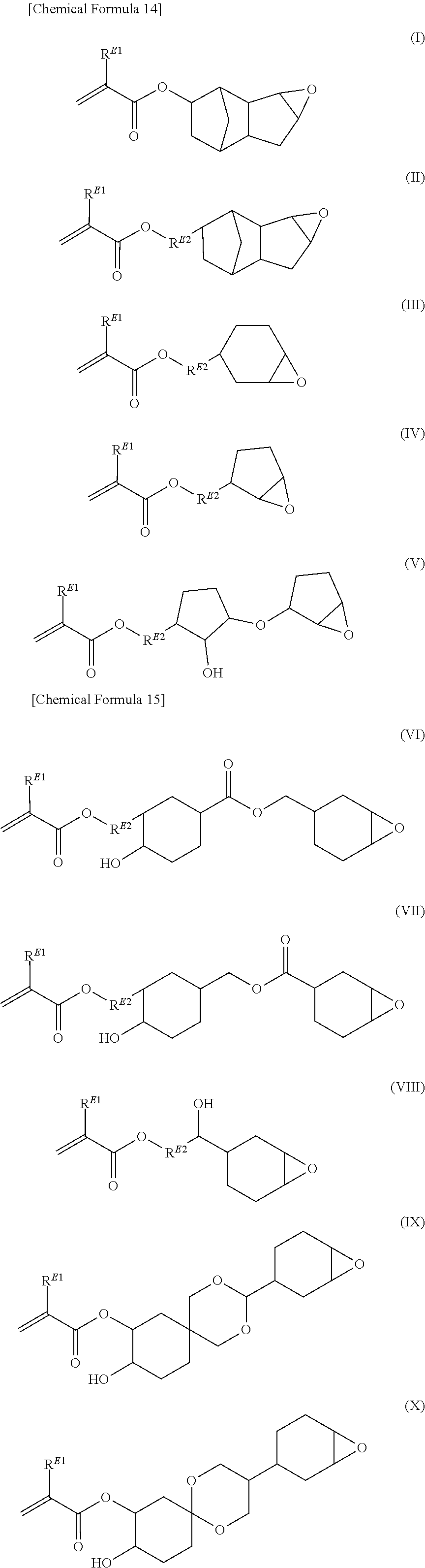

Herein, R^{E1}'s each independently are a hydrogen atom or a methyl group. R^{E2}'s each independently are an aliphatic saturated hydrocarbon group.

Examples of the aliphatic saturated hydrocarbon group represented by R^{E2} include a linear or branched alkylene group having 1 to 6 carbon atoms, a cycloalkylene group having 3 to 8 carbon atoms, an arylene group having 6 to 14 carbon atoms, and a divalent organic group consisting of a combination of these. Examples of the alkylene group include a methylene group, an ethylene group, a propylene group, a tetramethylene group, an ethylethylene group, a pentamethylene group, and a hexamethylene group. Examples of the cycloalkylene group include a cyclopentylene group, a cyclohexylene group, and a cyclooctylene group. Examples of the arylene group include a phenylene group and a naphthylene group. Examples of the divalent organic group consisting of a combination of these include —CH₂-phenylene group-CH₂—, —CH₂-cyclohexylene group-CH₂—.

From the viewpoint of pattern formability and reduction in tackiness, R^{E2} may be a methylene group, an ethylene group, a propylene group, a tetramethylene group, an ethylethylene group, a pentamethylene group, a hexamethylene group, a phenylene group, a cyclohexylene group, or —CH₂-phenylene group-CH₂—, may be a methylene group, an ethylene group, or a propylene group, and may be a methylene group.

From the viewpoint of pattern formability, the alicyclic epoxy group-containing unsaturated compound (e2) not having a carbon-nitrogen bond may be a compound represented by Formula (III) above.

Commercially available products may be used as the component (E), and examples thereof include (ACA)Z250 of Cyclomer P series (manufactured by DAICEL-ALLNEX LTD., acid value: 101.7 mgKOH/g). (ACA)Z250 is a resin consisting of three constituent units represented by Formula (XI) below produced by the reaction of an acid group-containing acrylic resin with an alicyclic epoxy group-containing unsaturated compound.

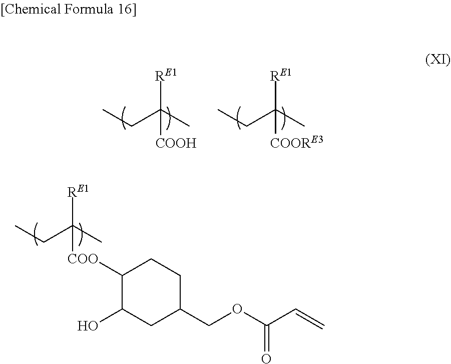

(In the formula, R^{E1} represents a hydrogen atom or a methyl group; and R^{E3} represents an alkyl group having 1 to 6 carbon atoms or a hydroxyalkyl group having 1 to 6 carbon atoms.)

The glass transition temperature of the component (E) is 70° C. to 150° C., may be 100° C. to 150° C., may be 115° C. to 150° C., and may be 125° C. to 150° C. Herein, the glass transition temperature of the component (E) is a value measured by the following method.

(Method of measuring glass transition temperature of component (E))

As a pretreatment for measurement, the component (E) was heated at 120° C. for 3 hours and then cooled to prepare a sample.

10 mg of the sample is used, the temperature is raised to a temperature range of 25° C. to 200° C. at a temperature increase rate of 20° C./min under a nitrogen gas stream by a differential scanning calorimeter (trade name: DSC-50 manufactured by SHIMADZU CORPORATION), and the influence of a solvent or the like is eliminated.

The temperature is cooled to 25° C., and raised again under the same conditions, and a temperature at which the baseline deviation starts is regarded as the glass transition temperature.

Furthermore, the weight average molecular weight of the component (E) may be 3,000 to 50,000, may be 4,000 to 40,000, and may be 5,000 to 30,000. When the weight average molecular weight is 3,000 or more, the tackiness suppression effect tends to increase, and when the weight average molecular weight is 50,000 or less, the resolution tends to be improved.

In a case where the photosensitive resin composition of the present embodiment contains the component (E), the content of the component (E) may be 5 to 60 parts by mass, may be 10 to 40 parts by mass, or may be 10 to 30 parts by mass, with respect to 100 parts by mass of the total of the component (A) and the component (E), from the viewpoint of pattern formability and the viewpoint of reducing tackiness.

<Component (F): silane compound>

Furthermore, the photosensitive resin composition of the present embodiment can further contain (F) a silane compound. A known silane coupling agent can be used as the component (F). The component (F) can improve the adhesiveness with the substrate of the electronic component, and is particularly effective in a case where the substrate is a substrate containing silicon (for example, a glass substrate, a silicon wafer, an epoxy resin-impregnated glass cloth substrate, or the like). Examples of the silane coupling agent include alkoxysilane such as methyltrimethoxysilane, methyltriethoxysilane, phenyltrimethoxysilane, and phenyltriethoxysilane; (meth)acryloyl group-containing alkoxysilane such as (meth)acryloxypropyltrimethoxysilane and (meth)acryloxypropylmethyldimethoxysilane; amine-based alkoxysilane such as γ-aminopropyltrimethoxysilane, γ-aminopropyltriethoxysilane, N-phenyl-3-aminopropyltrimethoxysilane, and 3-triethoxysilyl-N-(1,3-dimethylbutylidene)propylamine; glycidoxy group-containing alkoxysilane such as γ-glycidoxypropyltrimethoxysilane, γ-glycidoxypropyltriethoxysilane, glycidoxypropylmethyldiethoxysilane, and glycidoxypropylmethyldiisopropenoxysilane; alicyclic epoxy group-containing alkoxysilane such as 2-(3,4-epoxycyclohexyl)ethyltrimethoxysilane; ureide group-containing alkoxysilane such as 3-ureidopropyltriethoxysilane; mercapto group-containing alkoxysilane such as 3-mercaptopropyltrimethoxysilane, and 3-mercaptopropylmethyldimethoxysilane; carbamate group-containing alkoxysilane such as triethoxysilylpropylethylcarbamate; and polybasic acid anhydride group-containing alkoxysilane such as 3-(triethoxysilyl)propyl succinic acid anhydride. These can be used singly or in combination of two or more types thereof.

From the viewpoint of further improving adhesiveness, a silane coupling agent having an ethylenically unsaturated group in the molecule, such as (meth)acryloyl group-containing alkoxysilane such as (meth)acryloxypropyltrimethoxysilane and (meth)acryloxypropylmethyldimethoxysilane and glycidoxy group-containing alkoxysilane such as glycidoxypropyltrimethoxysilane, glycidoxypropylmethyldiethoxysilane, and glycidoxypropylmethyldiisopropenoxysilane, may be used.

In a case where the photosensitive resin composition of the present embodiment contains the component (F), the content of the component (F) may be appropriately selected from 0.05 to 15% by mass, 0.1 to 10% by mass, 0.1 to 7% by mass, 1 to 7% by mass, or 1 to 5% by mass, based on the total amount of solid contents of the photosensitive resin composition. With the above content, deterioration of the resist shape can be suppressed, and pattern formability can be improved.

<Component (G): thermal-radical polymerization initiator>

Furthermore, the photosensitive resin composition of the present embodiment can further contain (G) a thermal-radical polymerization initiator. The component (G) is not particularly limited, and examples thereof include peroxide-based polymerization initiators such as dialkyl peroxides such as α,α′-bis(t-butylperoxy)diisopropylbenzene, dicumyl peroxide, t-butylcumyl peroxide, and di-t-butylperoxide; ketone peroxides such as methylethylketone peroxide, cyclohexanone peroxide, and methylcyclohexanone peroxide; peroxy ketals such as 1,1-bis(t-butylperoxy)cyclohexane, 1,1-bis(t-butylperoxy)-2-methylcyclohexane, 1,1-bis(t-butylperoxy)-3,3,5-trimethylcyclohexane, 1,1-bis(t-hexylperoxy)cyclohexane, and 1,1-bis(t-hexylperoxy)-3,3,5-trimethylcyclohexane; hydroperoxides such as p-menthane hydroperoxide; diacyl peroxides such as octanoyl peroxide, lauroyl peroxide, stearyl peroxide, and benzoyl peroxide; peroxy carbonates such as bis(4-t-butylcyclohexyl)peroxy dicarbonate, di-2-ethoxyethyl peroxydicarbonate, di-2-ethylhexyl peroxydicarbonate, di-3-methoxybutyl peroxycarbonate; peroxyesters such as t-butyl peroxypivalate, t-hexyl peroxypivalate, 1,1,3,3-tetramethylbutyl peroxy-2-ethylhexanoate, 2,5-dimethyl-2,5-bis(2-ethylhexanoylperoxy)hexane, t-hexyl peroxy-2-ethylhexanoate, t-butyl peroxy-2-ethylhexanoate, t-butyl peroxyisobutyrate, t-hexyl peroxyisopropylmonocarbonate, t-butyl peroxy-3,5,5-trimethylhexanoate, t-butyl peroxylaurate, t-butyl peroxyisopropylmonocarbonate, t-butyl peroxy-2-ethylhexylmonocarbonate, t-butyl peroxybenzoate, t-hexyl peroxybenzoate, 2,5-dimethyl-2,5-bis(benzoylperoxy)hexane, and t-butyl peroxyacetate, and azo-based polymerization initiators such as 2,2′-azobisisobutyronitrile, 2,2′-azobis(2,4-dimethylvaleronitrile), and 2,2′-azobis(4-methoxy-2′-dimethylvaleronitrile).

From the viewpoint of improving pattern formability, the component (G) can be selected from a peroxide-based polymerization initiator and a dialkyl peroxide-based polymerization initiator, and among these, dicumyl peroxide can be selected. Furthermore, the component (G) can be used singly or in combination of two or more types thereof.

In a case where the photosensitive resin composition of the present embodiment contains the component (G), the content of the component (G) may be appropriately selected from 0.1 to 10% by mass, 0.2 to 5% by mass, or 0.3 to 1.5% by mass, based on the total amount of solid contents of the photosensitive resin composition. With the above content, the heat resistance of the photosensitive resin composition is improved, and reliability when the photosensitive resin composition is used as a permanent film is improved.

<Component (H): inorganic filler>

The photosensitive resin composition of the present embodiment can contain a component (H) for the purpose of further improving various properties such as the adhesiveness between the photosensitive resin composition and the substrate, heat resistance, and the rigidity of the cured product.

As the component (H), for example, silica (SiO₂), alumina (Al₂O₃), titania (TiO₂), tantalum oxide (Ta₂O₅), zirconia (ZrO₂), silicon nitride (Si₃N₄), barium titanate (BaO.TiO₂), barium carbonate (BaCO₃), magnesium carbonate (MgCO₃), aluminum hydroxide (Al(OH)₃), magnesium hydroxide (Mg(OH)₂), lead titanate (PbO.TiO₂), lead zirconate titanate (PZT), lead lanthanum zirconate titanate (PLZT), gallium oxide (Ga₂O₃), spinel (MgO.Al₂O₃), mullite (3Al₂O₃.2SiO₂), cordierite (2MgO.2Al₂O₃.5SiO₂), talc (3MgO.4SiO₂.H₂O), aluminum titanate (TiO₂.Al₂O₃), yttria-containing zirconia (Y₂O₃.ZrO₂), barium silicate (BaO.8SiO₂), boron nitride (BN), calcium carbonate (CaCO₃), barium sulfate (BaSO₄), calcium sulfate (CaSO₄), zinc oxide (ZnO), magnesium titanate (MgO.TiO₂), hydrotalcite, mica, calcined kaolin, carbon (C), and the like can be used. These inorganic fillers can be used singly or in combination of two or more types thereof.

The average particle size of the component (H) may be appropriately selected from 0.01 to 3 μm, 0.01 to 2 μm, or 0.02 to 1 μm from the viewpoint of improving adhesiveness, heat resistance, and the rigidity of the cured product. Herein, the average particle size of the component (H) is an average particle size of an inorganic filler in a state of being dispersed in the photosensitive resin composition and is a value obtained by performing measurement as described below. First, the photosensitive resin composition is diluted (or dissolved) 1000 times with methyl ethyl ketone, particles dispersed in the solvent are then measured at a refractive index of 1.38 using a submicron particle analyzer (trade name: N5 manufactured by Beckman Coulter, Inc.) according to

International Standardization Organization ISO 13321, and the particle size corresponding to the integrated values of 50% in the particle size distribution (volume basis) is regarded as the average particle size. Furthermore, also regarding the component (H) contained in the photosensitive layer provided on the carrier film or the cured film of the photosensitive resin composition, the component (H) is diluted (or dissolved) 1000 times (volume ratio) using a solvent as described above, and then can be measured by using the above-described submicron particle analyzer.

In a case where the photosensitive resin composition of the present embodiment contains the component (H), the upper limit of the content of the component (H) may be appropriately selected from 10% by mass or less, 5% by mass or less, or 1% by mass or less, based on the total amount of solid contents of the photosensitive resin composition, the lower limit thereof may be appropriately selected from more than 0% by mass, and may be 0% by mass (that is, the component (H) may not be contained). In this way, when the component (H) is not substantially contained, the transmittivity of the photosensitive resin composition is improved, and for example, even in the case of forming a pattern with a thick photosensitive layer having a thickness of 70 μm or more, light is likely to pass through to the bottom of the photosensitive layer (the surface of the photosensitive layer on the substrate side), so that pattern formability is improved.

<Secondary Thiol Compound>

The photosensitive resin composition of the present embodiment may contain a secondary thiol compound. In a case where the secondary thiol compound is added to the photosensitive resin composition, the content of the secondary thiol compound may be 0.02 to 1.0% by mass, 0.02 to 0.4% by mass, or 0.02 to 0.2% by mass, based on the total amount of solid contents of the photosensitive resin composition. When the content of the secondary thiol compound is 0.02% by mass or more, the resolution on the copper surface tends to be further improved, and when the content thereof is 1.0% by mass or less, high resolution in a state where the residue is reduced tends to be possible.

<Other Additives>

The photosensitive resin composition of the present embodiment can further contain additives such as a sensitizer, heat-resistant high molecular weight compound, a thermal crosslinking agent, and an adhesion assistant other than the above-described component (F), as necessary.

Examples of the sensitizer include sensitizers such as pyrazolines, anthracenes, xanthones, oxazoles, benzoxazoles, thiazoles, benzothiazoles, triazoles, stilbenes, triazines, thiophenes, and naphthalimides. These can be used singly or in combination of two or more types thereof.

From the viewpoint of improving workability, examples of the heat-resistant high molecular weight compound include polyoxazole and precursors thereof, a novolak resin such as phenol novolak or cresol novolak, polyamideimide, and polyamide, which have heat resistance and are used as engineering plastics. These can be used singly or in combination of two or more types thereof.

From the viewpoint of improving the rigidity of the cured product, examples of the thermal crosslinking agent include an epoxy resin, a phenolic resin in which an a-position is substituted with a methylol group or an alkoxymethyl group, a melamine resin in which an N-position is substituted with at least one selected from the group consisting of a methylol group and an alkoxymethyl group, and a urea resin. These can be used singly or in combination of two or more types thereof.

The content of these other additives is not particularly limited as long as it is a range that does not impair the effect of the photosensitive resin composition of the present embodiment, and for example, the content thereof may be appropriately selected from 0.1 to 10% by mass, 0.3 to 5% by mass, or 0.5 to 5% by mass, based on the total amount of solid contents.

<Diluent>

In the photosensitive resin composition of the present embodiment, a diluent can be used as necessary. Examples of the diluent include polar solvents such as alcohols having 1 to 6 carbon atoms such as isopropanol, isobutanol, and t-butanol; amides such as N,N-dimethylformamide, N,N-dimethylacetamide, and N-methylpyrrolidone; sulfur atom-containing compounds such as dimethylsulfoxide and sulfolane; esters such as y-butyrolactone and dimethyl carbonate; and esters such as cellosolve acetate, ethyl cellosolve acetate, butyl cellosolve acetate, carbitol acetate, ethyl carbitol acetate, butyl carbitol acetate, propylene glycol monomethyl ether acetate, and propylene glycol monoethyl ether acetate. These can be used singly or in combination of two or more types thereof.

The amount of the diluent used may be appropriately selected from such an amount that the content of the total amount of solid contents in the photosensitive resin composition is 50 to 90% by mass, 60 to 80% by mass, or 65 to 75% by mass. That is, the content of the diluent in the photosensitive resin composition in the case of using the diluent may be appropriately selected from 10 to 50% by mass, 20 to 40% by mass, or 25 to 35% by mass. When the amount of the diluent used is within the above range, the coating properties of the photosensitive resin composition are improved, and a higher definition pattern can be formed.

Furthermore, for example, in a case where a photosensitive layer having a thickness of 70 μm or more is desired to be formed, in consideration of ease of formation of a photosensitive layer, the amount of the diluent used can be set to such an amount that the viscosity of the photosensitive resin composition at 25° C. is 0.5 to 20 Pa·s or 1 to 10 Pa·s.

The photosensitive resin composition of the present embodiment can be obtained by uniformly kneading and mixing the above-described components (A) to (D), the components (E) to (H) that are used as desired, other additives, and the diluent by a roll mill, a bead mill, or the like.

The photosensitive resin composition of the present embodiment may be used as a liquid and may be used in the form of a film.

In the case of using the photosensitive resin composition as a liquid, a method of coating the photosensitive resin composition of the present embodiment is not particularly limited, and examples thereof include various coating methods such as a printing method, a spin coating method, a spray coating method, a jet dispensing method, an inkjet method, and a dip-coating method. Among these, from the viewpoint of more easily forming a thick photosensitive layer, the coating method may be appropriately selected from a printing method or a spin coating method.

Furthermore, in the case of using the photosensitive resin composition in the form of a film, for example, the form of a photosensitive resin film described below can be used, and in this case, a photosensitive layer having a desired thickness can be formed by lamination using a laminator or the like.

The absorbance for light with a wavelength of 365 nm at a thickness (thickness after drying) 50 μm of the photosensitive layer formed by the photosensitive resin composition of the present embodiment can be appropriately selected from 0.35 or less, 0.3 or less, 0.2 or less, or 0.1 or less. When the absorbance of the photosensitive layer at a thickness 50 μm of the photosensitive layer is 0.35 or less, for example, even in the case of forming a pattern with a thick photosensitive layer having a thickness of 70 μm or more, light is easy to pass properly through to the bottom of the photosensitive layer (the surface of the photosensitive layer on the substrate side), and thus pattern formability can be improved. Note that, the absorbance for light with a wavelength of 365 nm at a thickness 50 μm of the photosensitive layer can also be determined by converting the absorbance measured for a photosensitive layer having a thickness other than 50 μm into the absorbance at a thickness 50 μm based on Lambert-Beer law.

[Photosensitive Resin Film]

A photosensitive resin film of the present embodiment has a photosensitive layer using the photosensitive resin composition of the present embodiment. The photosensitive resin film of the present embodiment may have a carrier film. In the present specification, the term “layer” includes a structure having a shape which is formed on a part, in addition to a structure having a shape which is formed on the whole surface, when the layer has been observed as a plan view.

The photosensitive resin film of the present embodiment can be produced, for example, by coating the photosensitive resin composition of the present embodiment on a carrier film by the above-described various coating methods to form a coating film and drying the coating film to form a photosensitive layer. Furthermore, when the photosensitive resin composition of the present embodiment contains a diluent, at least a part of the diluent may be removed at the time of drying.

In the drying of the coating film, a dryer or the like using hot air drying, far infrared rays, or near infrared rays can be used, and the drying temperature may be appropriately selected from 60° C. to 120° C., 70° C. to 110° C., or 90° C. to 110° C. Furthermore, the drying time may be appropriately selected from 1 to 60 minutes, 2 to 30 minutes, or 5 to 20 minutes. If the coating film is dried under the above conditions, in a case where the photosensitive resin composition of the present embodiment contains a diluent, at least a part of the diluent can also be removed.

Examples of the carrier film include resin films such as a polyolefin resin film such as polyethylene terephthalate (PET), polybutylene terephthalate (PBT), or polyethylene naphthalate (PEN) and a polyolefin resin film such as polypropylene or polyethylene. From the viewpoint of improving the mechanical strength and the heat resistance of the photosensitive resin film, a polyester resin film may be selected.

The thickness of the carrier film may be appropriately selected from 10 μm to 3 mm, or 10 to 200 μm, in consideration of handleability or the like.

The thickness of the photosensitive layer may be appropriately selected from 1 to 500 μm, 10 to 300 μm, or 30 to 100 μm. By setting the thickness to 30 μm or more, for example, in the case of forming a photosensitive layer having a thickness of 150 μm or more, the number of times of work by laminating or the like can be further reduced. Furthermore, by setting the thickness to 100 μm or less, when the photosensitive resin film is wound around a winding core, the deformation of the photosensitive layer due to a difference in stress between the inside and the outside of the winding core can be further reduced. Considering the effect of obtaining excellent pattern formability of the photosensitive resin composition of the present embodiment even in the case of forming a thick photosensitive layer, the thickness of the photosensitive layer may be 70 μm or more and may exceed 100 μm. Note that, a photosensitive layer having a thickness of 70 μm or more may be formed, for example, by pasting one in which a photosensitive layer is formed on a carrier film and one in which a photosensitive layer is formed on a protective layer described below. Thereby, a photosensitive resin film including a carrier film, a thick photosensitive layer, and a protective layer in this order can be obtained.

Furthermore, the photosensitive resin film of the present embodiment can be laminated with the protective layer on a surface of the photosensitive layer opposite to a surface in contact with the carrier film. As the protective layer, for example, a resin film such as polyethylene or polypropylene, and the like may be used. Furthermore, the same resin film as the aforementioned carrier film may be used, and a resin film different from the carrier film may be used.

[Method for producing cured product]

A method for producing a cured product of the present embodiment includes: a step of providing a photosensitive layer by using the photosensitive resin composition or the photosensitive resin film of the present embodiment on a substrate (photosensitive layer formation step); a step of irradiating at least a part of the photosensitive layer with an active ray to form a photocured part (exposure step); and a step of removing at least a part of the photosensitive layer other than the photocured part to form a resin pattern (removal step), in the stated order. The method further includes, as desired, a step of heat-treating the photosensitive layer provided on the substrate in the photosensitive layer formation step (first heating step). Furthermore, the method further includes, as desired, a step of heat-treating the resin pattern (second heating step). The method for producing a cured product of the present embodiment enables a desired pattern to be formed, and by utilizing the feature of the photosensitive resin composition of the present embodiment that has excellent pattern formability, for example, even in the case of forming a thick photosensitive layer having a thickness of 70 μm or more, a desired pattern can be formed, for example, by a thick photosensitive layer having a thickness of 70 μm or more. In the present specification, the term “step” includes not only an independent step but also a step by which an intended action of the step is achieved, even though the step cannot be clearly distinguished from other steps.

(Photosensitive Layer Formation Step)

In the formation of a photosensitive layer, a photosensitive layer can be formed by respectively coating or laminating the photosensitive resin composition or the photosensitive resin film of the present embodiment on a substrate.

Examples of the substrate include a glass substrate, a silicon wafers, a metal oxide insulator such as TiO₂ or SiO₂, silicon nitride, a ceramic piezoelectric substrate, and an epoxy resin-impregnated glass cloth substrate. Furthermore, the substrate may be a substrate having a copper surface such as copper wiring on a part of the surface. According to the photosensitive resin composition of the present embodiment, in the case of forming a resist pattern on such a substrate of which a part of the surface is a copper surface, excellent pattern formability can be realized under the same exposure conditions on surfaces of both of a site of a substrate having a copper surface and a site of the substrate not having a copper surface, and the occurrence of development residue on the copper surface can be suppressed.

In the case of forming a photosensitive layer by coating the photosensitive resin composition to a substrate, the photosensitive resin composition in the form of a solution prepared by dissolving the photosensitive resin composition in the above-described diluent may be coated to the substrate, and a coating film obtained by coating may be dried as necessary. The coating and drying may be formed by various coating methods described in the production of the photosensitive resin film described above, and the method of drying the coating film.

Furthermore, in the case of using the photosensitive resin film, a photosensitive layer can be formed by a laminating method using a laminator or the like.

The thickness of the photosensitive layer provided on the substrate varies depending on the formation method (the coating method or the laminating method), the solid content concentration and the viscosity of the photosensitive resin composition, and the like, and the lower limit of the thickness of the photosensitive layer after drying may be appropriately selected from 10 μm or more, 30 μm or more, 50 μm or more, 70 μm or more, 100 μm or more, more than 100 μm, or 150 μm or more. Furthermore, the upper limit of the thickness is not particularly limited as long as a resin pattern can be formed, and for example, may be appropriately selected from 500 μm or less, 300 μm or less, or 250 μm or less. The thickness of the photosensitive layer may be appropriately selected from the above ranges according to the use application. In the case of using the photosensitive layer in an electronic component or the like, the lower limit may be appropriately selected from 70 μm or more, more than 100 μm, or 150 μm or more, and the upper limit may be appropriately selected from 500 μm or less, 300 μm or less, or 250 μm or less.

In the method for producing a cured product of the present embodiment, since a photosensitive layer is formed using the photosensitive resin composition of the present embodiment, a thick photosensitive layer can be formed. For example, in the case of forming a photosensitive layer having a thickness of 150 μm or more, the photosensitive layer is not formed by performing coating (and, as necessary, drying) or laminating once, but is formed by repeating coating (and, as necessary, drying) or laminating multiple times until a desired thickness is reached.

(First Heating Step)

The first heating step is a step that is adopted as necessary, and is a step of heat-treating the photosensitive layer provided on the substrate in the photosensitive layer formation step. The heating temperature may be appropriately selected from 50° C. to 120° C., 70° C. to 110° C., or 90° C. to 100° C. Furthermore, the heating time may be appropriately selected from 30 seconds to 30 minutes, 1 minute to 15 minutes, or 5 minutes to 10 minutes. By performing the first heating step, the triazole-based compound is easily coordinated on the copper surface, and a triazole-based compound layer is easily formed at an interface between the photosensitive layer and the copper surface. As a result, contact between the organic matter in the photosensitive layer other than the triazole-based compound and the copper surface is effectively inhibited, and it is possible to further suppress that the organic matter adheres to the copper surface to become development residue.

(Exposure Step)

In the exposure step, at least a part of the photosensitive layer provided on the substrate in the photosensitive layer formation step is irradiated with an active ray as necessary to photocure the exposed part, thereby forming a cured part. At the time of irradiation with active lays, the photosensitive layer may be irradiated with active lays through a mask having a desired pattern, and may be irradiated with active lays by a direct drawing exposure method such as an LDI (Laser Direct Imaging) exposure method or a DLP (Digital Light Processing) exposure method.

Furthermore, from the viewpoint of improving pattern formability, after exposure, post exposure bake (PEB) using a hot plate, a dryer, or the like may be performed. The drying conditions are not particularly limited, and the drying may be performed at a temperature of 60° C. to 120° C. or 70° C. to 110° C. in a time of 15 seconds to 5 minutes or 30 seconds to 3 minutes.

The exposure amount of an active ray may be appropriately selected from 10 to 2000 mJ/cm², 100 to 1500 mJ/cm², or 300 to 1000 mJ/cm². Examples of the active ray to be used include ultraviolet rays, visible rays, electron beams, and X-rays. Furthermore, as a light source, a low-pressure mercury lamp, a high-pressure mercury lamp, an ultra-high pressure mercury lamp, a halogen lamp, and the like can be used.

(Removal Step)

In the removal step, at least a part of a part (unexposed part) of the photosensitive layer formed in the exposure step other than the cured part is removed to form a resin pattern. The removal of the unexposed part may be performed, for example, using a developer such as an organic solvent.

Examples of the organic solvent include ethanol, cyclohexanone, cyclopentanone, propylene glycol methyl ether acetate, and N-methylpyrrolidone. Particularly, from the viewpoint of a developing speed, cyclopentanone can be used. These can be used singly or in combination of two or more types thereof.

Furthermore, various additives that can be generally used may be added into the organic solvent used as a developer.

Furthermore, after the unexposed part is removed by the developer, as necessary, washing (rinsing) with water, alcohol such as methanol, ethanol, or isopropyl alcohol, n-butyl acetate, propylene glycol monomethyl ether acetate, diethylene glycol dimethyl ether acetate, or the like may be performed.

(Second Heating Step)

The second heating step is a step that is adopted as necessary, and is a step of heat-treating the resin pattern formed in the removal step to form a cured product. The heat treatment is preferably performed for 1 to 2 hours while selecting the heating temperature and increasing the temperature in a stepwise manner. The heating temperature may be appropriately selected from 120° C. to 240° C., 140° C. to 230° C., or 150° C. to 220° C. Furthermore, in the case of increasing the temperature in a stepwise manner, for example, the heat treatment may be performed at a temperature of at least one of around 120° C. and around 160° C. for 10 to 50 minutes or 20 to 40 minutes, and then the heat treatment may be performed around 220° C. for 30 to 100 minutes or 50 to 70 minutes.

The thickness of the obtained resin pattern is the same as the thickness of the photosensitive layer after drying described above, and the lower limit may be appropriately selected from 10 μm or more, 30 μm or more, 50 μm or more, 70 μm or more, 100 μm or more, more than 100 μm, or 150 μm or more, and the upper limit may be appropriately selected from 500 μm or less, 300 μm or less, or 250 μm or less. The thickness of the resin pattern may be appropriately selected from the above ranges according to the use application. In the case of using the resin pattern in an electronic component or the like, the lower limit may be appropriately selected from 70 μm or more, more than 100 μm, or 150 μm or more, and the upper limit may be appropriately selected from 500 μm or less, 300 μm or less, or 250 μm or less.

[Laminate]

A laminate of the present embodiment includes a cured product of the photosensitive resin composition of the present embodiment, and for example, a laminate, which includes the cured product on various supports such as a substrate and a carrier film of a photosensitive resin film to be used in the above-described method for producing a cured product, is exemplified. The cured product of the photosensitive resin composition of the present embodiment can be formed, for example, by the method for producing a cured product of the present embodiment described above.

Regarding the thickness of the cured product in the laminate of the present embodiment, the lower limit may be appropriately selected from 10 μm or more, 30 μm or more, 50 μm or more, 70 μm or more, 100 μm or more, more than 100 μm, or 150 μm or more, and the upper limit may be appropriately selected from 500 μm or less, 300 μm or less, or 250 μm or less. The thickness of the cured product may be appropriately selected from the above ranges according to the use application. In the case of using the cured product in an electronic component or the like, the lower limit may be appropriately selected from 70 μm or more, more than 100 μm, or 150 μm or more, and the upper limit may be appropriately selected from 500 μm or less, 300 μm or less, or 250 μm or less.

The cured product provided on the substrate obtained by the above-described method for producing a cured product can respond to, for example, requests related to electronic circuit boards in which a thick cured product is required to be provided on a substrate with a finer pattern with the trend of miniaturization and high performance of electronic devices, since excellent pattern formability is obtainable by using the photosensitive resin composition of the present embodiment, for example, even in the case of a thick photosensitive layer having a thickness of 70 μm or more. Furthermore, for example, in the plating treatment step in the manufacturing of electronic circuit boards, by using the cured product formed by the photosensitive resin composition of the present embodiment as an insulating film, a decrease in yield due to short circuit between wirings can be suppressed.

Therefore, the laminate of the present embodiment can be used, for example, as an electronic component of an electronic circuit board or the like in mobile terminals such as cellular phones.

Furthermore, according to the above-described method for producing a cured product, in the case of forming a resist pattern on a substrate having a copper surface such as copper wiring on a part of the surface by using the photosensitive resin composition of the present embodiment, excellent pattern formability can be realized under the same exposure conditions on surfaces of both of a site of a substrate having a copper surface and a site of the substrate not having a copper surface, and the occurrence of development residue on the copper surface can be suppressed.

Therefore, the laminate of the present embodiment can be used, for example, as an electronic component of an electronic circuit board or the like, such as an inductor.

### EXAMPLES

Hereinafter, the object and advantages of the present embodiment will be described in more detail based on Examples and Comparative Examples; however, the present embodiment is not limited to the following Examples. Note that, the method for measuring the weight average molecular weight of each component and the method for measuring the glass transition temperature of the component (E) are as follows.

(Measurement of Weight Average Molecular Weight)

The weight average molecular weight is a value determined by the GPC method in terms of standard polystyrene using the following apparatus, and was measured using a solution obtained by dissolving 0.5 mg of polymer in 1 mL of tetrahydrofuran (THF).
Apparatus name: HLC-8320GPC manufactured by Tosoh Corporation
Column: Gelpack R-420, R-430, and R-440 (three columns connected)
Detector: RI detector
Column temperature: 40° C.
Eluent: THF
Flow rate: 1 ml/min
Standard substance: Polystyrene

(Measurement of Glass Transition Temperature of Component (E))

As a pretreatment for measurement, the component (E) was heated at 120° C. for 3 hours and then cooled to prepare a sample.

10 mg of the sample was used, the temperature was raised to a temperature range of 25° C. to 200° C. at a temperature increase rate of 20° C./min under a nitrogen gas stream by a differential scanning calorimeter (trade name: DSC-50 manufactured by SHIMADZU CORPORATION), then cooled to 25° C., and raised again under the same conditions, and a temperature at which the baseline deviation starts was regarded as the glass transition temperature.

### Examples 1 to 7 and Comparative Examples 1 and 2

Compositions were blended according to the blending composition shown in Table 1 (the unit of numerical value in the table is the mass part, and in the case of a solution, is the amount in terms of solid content) and kneaded with a three roll mill to prepare a photosensitive resin composition. N,N-dimethyl acetamide was added thereto so that the solid content concentration became 60% by mass to obtain a photosensitive resin composition.

Next, each evaluation was performed using the photosensitive resin composition obtained above by the method described below. The evaluation results are shown in Table 1.

[Production of Photosensitive Resin Film]

A polyethylene terephthalate film having a thickness of 50 μm (trade name: A-4100 manufactured by TEIJIN LIMITED) was used as a carrier film, each of the photosensitive resin compositions of Examples and Comparative Examples was uniformly coated onto the carrier film such that the thickness after drying would be 50 μm. Next, the photosensitive resin composition was dried by heating at 100° C. for 15 minutes using a hot air convection drier to form a photosensitive layer, thereby producing a photosensitive resin film having the carrier film and the photosensitive layer.

[Evaluation of Pattern Formability (Resolution)]

As a substrate, a glass epoxy substrate having a copper surface (trade name: MCL-E-679FGB, manufactured by Hitachi Chemical Co., Ltd., hereinafter, also referred to as “Cu-containing substrate”) and a substrate obtained by etching copper of the glass epoxy substrate (hereinafter, also referred to as “Cu-free substrate”) were prepared. The photosensitive resin film was laminated on the substrate in a direction in which the photosensitive layer is positioned on the glass epoxy substrate side, and the carrier film was removed. The lamination was performed at 60° C. using a laminator. Next, the photosensitive resin film was laminated again on the photosensitive layer by the above-described method and the carrier film was removed. This operation was repeated three times to obtain a laminate including the photosensitive layer having a thickness of 200 μm and the carrier film on the glass epoxy substrate. Herein, in Examples 2, 6, and 7, the heat treatment of further heating the laminate produced by the above-described method at 90° C. for 5 minutes (first heating step) was performed.

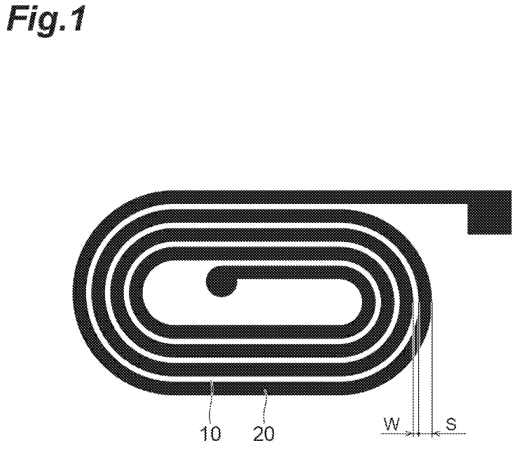

Drawing data (line space: three types of 70 μm, 50 μm, 30 μm, all of the line widths are 12 μm) having a pattern shape illustrated in FIG. 1 as the exposed part was exposed from the carrier film side of the laminate by using a direct drawing exposure apparatus with a main wavelength of 355 nm using a semiconductor laser as a light source (trade name: Paragon 9000 manufactured by Orbotech Ltd.). At this time, the laminate was divided into three regions, and the three regions were exposed at different exposure amounts (120 mJ/cm², 150 mJ/cm², and 180 mJ/cm²). The exposed sample was subjected to post exposure bake for 1 minute on a hot plate set at 90° C. Note that, the drawing data illustrated in FIG. 1 has an exposed part 10 and a non-exposed part 20, and a width W of the exposed part 10 corresponds to the line width and a width S of the non-exposed part 20 corresponds to line space.

Thereafter, the carrier film was removed and the pattern was developed by immersing in a developer (cyclopentanone) for 20 minutes. The developed pattern was dried at room temperature for 30 minutes and the pattern formability was evaluated by observing the pattern using a metallurgical microscope. The evaluation was conducted on the following criteria. Herein, “formable” means that the unexposed part is cleanly removed, and there is no defect such as rucking of the line part (exposed part) and burying of the space part. The evaluation results are shown in Table 1.
A: The pattern was formable with a line space of 30 μm.
B: Although the pattern was not formable with a line space of 30 μm, the pattern was formable with a line space of 50 μm.
C: Although the pattern was not formable with a line space of 50 μm or less, the pattern was formable with a line space of 70 μm.
D: The pattern was not formable with none of line spaces.

Furthermore, the resolution mismatch elimination performance was evaluated based on the following criteria. A case where this evaluation result is “A” or “B” is acceptable. In a case where this evaluation result is “A”, it can be determined that excellent pattern formability can be realized under the same exposure conditions on surfaces of both of a site of a substrate having a copper surface and a site of the substrate not having a copper surface.
A: There is an exposure amount that makes pattern formability under the same exposure amount evaluation “A” in both of the Cu-containing substrate and the Cu-free substrate.
B: There is an exposure amount that makes pattern formability under the same exposure amount evaluation “A” or “B” in both of the Cu-containing substrate and the Cu-free substrate.
C: There is no exposure amount that makes pattern formability under the same exposure amount evaluation “A” or “B” in both of the Cu-containing substrate and the Cu-free substrate.

[Development Residue Evaluation on Glass Epoxy Substrate having Copper Surface]

As for the Cu-containing substrate after development produced in the evaluation of the pattern formability, the development residue was evaluated by observing the copper surface of a part obtained by removing the photosensitive layer by development using a metallurgical microscope. The evaluation was performed on the following criteria by observing the copper surface in a case where the copper surface was exposed and developed at an exposure amount at which pattern formability is most favorable with a line space of 70 μm. A case where this evaluation result is “A” is acceptable. The evaluation results are shown in Table 1.
A: The color of the copper surface itself is shown. This indicates that there is almost no residue.
B: An interference fringe (iridescence) is observed. This indicates that there is a small amount of residue.
C: The organic matter (white) of the residue is observed. This indicates that there is a large amount of residue.

TABLE 1

| | | | Example | Example | Example | Example | Example | Example | Example | Comparative | Comparative |
|---|---|---|---|---|---|---|---|---|---|---|---|
| | | | 1 | 2 | 3 | 4 | 5 | 6 | 7 | Example 1 | Example 2 |
| Component (A) | UN-954 | | 50 | 50 | 50 | 50 | 50 | 80 | 40 | 50 | 80 |
| Component (E) | Z250 | | 50 | 50 | 50 | 50 | 50 | 20 | 60 | 50 | 20 |
| Component (B) | A-9300 | | 14 | 14 | 14 | 14 | 14 | 14 | 14 | 14 | 14 |
| | TMCH-5R | | 56 | 56 | 56 | 56 | 56 | 56 | 56 | 56 | 56 |
| Component (C) | I-184 | | 10 | 10 | 10 | 10 | 10 | 10 | 10 | 10 | 10 |
| Component (F) | KBM-503 | | 1 | 1 | 1 | 1 | 1 | 1 | 1 | 1 | 1 |
| | KBM-803 | | — | — | — | — | — | — | — | — | 5 |
| Component (D) | BT | | 1.5 | 1.5 | 4 | 7 | 10 | 1.5 | 1.5 | — | — |
| Presence/absence of first heating step | | | Absent | Present | Absent | Absent | Absent | Present | Present | Absent | Absent |
| Pattern | Cu-free | 120 mJ/cm² | D | D | D | D | D | D | D | D | D |
| formability | substrate | 150 mJ/cm² | A | A | A | A | D | A | A | A | D |
| | | 180 mJ/cm² | B | B | A | A | A | B | B | A | D |
| | Cu- | 120 mJ/cm² | B | D | B | A | D | B | D | B | D |
| | containing | 150 mJ/cm² | B | A | B | B | B | B | A | C | D |
| | substrate | 180 mJ/cm² | B | B | B | B | B | B | B | C | D |

| | | | | | | | | | |
|---|---|---|---|---|---|---|---|---|---|
| Mismatch elimination | B | A | B | B | B | B | A | C | C |
| performance | | | | | | | | | |

| | | | | | | | | | |
|---|---|---|---|---|---|---|---|---|---|
| Observation result of residue | A | A | A | A | A | A | A | B | C |
| on Cu after development | | | | | | | | | |

The details of each material in Table 1 are as follows.

[Component (A)]
UN-954: Urethane acrylate (manufactured by Negami Chemical Industrial Co., Ltd., trade name, number of functional groups: 6, weight average molecular weight (Mw): 4,500)

[Component (B)]
A-9300: Isocyanurate ethylene oxide-modified triacrylate (manufactured by SHIN-NAKAMURA CHEMICAL Co., Ltd., molecular weight: 423, being a compound represented by Formula (7-1) below and corresponding to the component (B1))
TMCH-5R: Urethane acrylate (manufactured by Hitachi Chemical Co., Ltd., trade name, number of functional groups: 2, weight average molecular weight (Mw): 950, being a compound having an acryloyl group (photopolymerizable functional group), a urethane bond (carbon-nitrogen bond), a chain hydrocarbon skeleton, and an alicyclic hydrocarbon skeleton in the molecule and corresponding to the component (B2))

[Component (C)]
1-184: “IRGACURE-184” (manufactured by BASF, trade name) that is 1-hydroxy-cyclohexyl-phenyl-ketone

[Component (D)]
BT: Benzotriazole (manufactured by Tokyo Chemical Industry Co., Ltd., trade name: 1,2,3-benzotriazole)

[Component (E)]
Z250: CYCLOMER-P (ACA)Z250 (manufactured by DAICEL-ALLNEX LTD., a resin composed of three constituent units represented by Formula (XI) above and produced by reaction of an acid group-containing acrylic resin with an alicyclic epoxy group-containing unsaturated compound (weight average molecular weight: 19,000 to 25,000))

[Component (F)]
KBM-503: 3-Methacryloxypropyl trimethoxysilane (manufactured by Shin-Etsu Chemical Co., Ltd., trade name)
KBM-803: 3-Mercaptopropyl trimethoxysilane (manufactured by Shin-Etsu Chemical Co., Ltd., trade name)

From Table 1, it was confirmed that the photosensitive resin compositions of Examples 1 to 7 have excellent pattern formability even on a copper surface of a Cu-containing substrate by adjusting the exposure amount, can eliminate mismatching of pattern formability on a Cu-free substrate and a Cu-containing substrate, and can reduce the development residue on the Cu surface after development.

1. A photosensitive resin composition comprising:
a component (A) which is a high molecular weight compound having a photopolymerizable functional group and a carbon-nitrogen bond;
a component (B) which is a low molecular weight compound having a photopolymerizable functional group;
a component (C) which is a photopolymerization initiator; and
a component (D) which is a triazole-based compound.

2. The photosensitive resin composition according to claim 1, wherein the component (D) comprises a benzotriazole-based compound.

3. The photosensitive resin composition according to claim 1, wherein a content of the component (D) is 0.1 to 10% by mass based on a total amount of solid contents of the photosensitive resin composition.

4. The photosensitive resin composition according to claim 1, wherein the component (A) comprises a high molecular weight compound having a (meth)acryloyl group as the photopolymerizable functional group.

5. The photosensitive resin composition according to claim 1, wherein the component (A) comprises a high molecular weight compound having a urethane bond as the carbon-nitrogen bond.

6. The photosensitive resin composition according to claim 1, wherein the component (A) comprises a high molecular weight compound having six or more ethylenically unsaturated groups as the photopolymerizable functional group and having a weight average molecular weight of 2,500 or more.

7. The photosensitive resin composition according to claim 1, wherein the component (A) comprises a high molecular weight compound having at least one skeleton selected from the group consisting of a chain hydrocarbon skeleton, an alicyclic skeleton, and an aromatic ring skeleton.

8. The photosensitive resin composition according to claim 1, wherein the component (B) comprises at least one selected from the group consisting of a low molecular weight compound having a urethane bond, a low molecular weight compound having an isocyanuric ring, and a low molecular weight compound having an alicyclic skeleton.

9. The photosensitive resin composition according to claim 1, wherein the component (B) comprises a low molecular weight compound having at least one (meth)acryloyl group and a urethane bond.

10. The photosensitive resin composition according to claim 1,
wherein the component (C) comprises a compound represented by General Formula (C1): 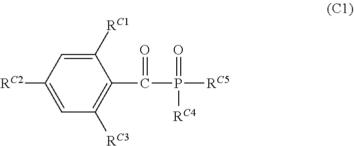
wherein R^{C1}, R^{C2}, and R^{C3} each independently represents a hydrogen atom, an alkyl group having 1 to 6 carbon atoms, or an alkoxy group having 1 to 6 carbon atoms,
wherein R^{C4} and R^{C5} each independently represents a hydrogen atom, an alkyl group having 1 to 6 carbon atoms, an alkoxy group having 1 to 6 carbon atoms, or an aryl group having 6 to 12 carbon atoms, and
wherein each of R^{C1} to R^{C5} other than the hydrogen atom optionally has a substituent.

11. The photosensitive resin composition according to claim 1, further comprising a component (E) which is a high molecular weight compound having a glass transition temperature of 70° C. to 150° C. and not having a carbon-nitrogen bond.

12. The photosensitive resin composition according to claim 1, further comprising a component (F) which is a silane compound.

13. A photosensitive resin film comprising a photosensitive layer formed of the photosensitive resin composition according to claim 1.

14. A method for producing a cured product, the method comprising:
providing a photosensitive layer on a substrate by using the photosensitive resin composition according to claim 1;
irradiating at least a part of the photosensitive layer with an active ray to form a photocured part; and
removing at least a part of the photosensitive layer other than the photocured part to form a resin pattern.

15. The method according to claim 14, further comprising heat-treating the resin pattern.

16. The method according to claim 14, wherein a thickness of the resin pattern is more than 100 μm and equal to or less than 300 _{J}im.

17. The method according to claim 14, further comprising heat-treating the photosensitive layer after the photosensitive layer is provided on a substrate.

18. A laminate comprising a cured product of the photosensitive resin composition according to claim 1.

19. The laminate according to claim 18, wherein a thickness of the cured product is more than 100 μm and equal to or less than 300 μm.

20. An electronic component comprising a cured product of the photosensitive resin composition according to claim 1.

21. A method for producing a cured product, the method comprising:
providing a photosensitive layer on a substrate by using the photosensitive resin film according to claim 13;
irradiating at least a part of the photosensitive layer with an active ray to form a photocured part; and
removing at least a part of the photosensitive layer other than the photocured part to form a resin pattern.

22. The method according to claim 21, further comprising heat-treating the resin pattern.

23. The method according to claim 21, wherein a thickness of the resin pattern is more than 100 μm and equal to or less than 300 μm.

24. The method according to 21, further comprising heat-treating the photosensitive layer after the photosensitive layer is provided on a substrate.

25. The photosensitive resin composition according to claim 1,
wherein the component (C) comprises a compound represented by General Formula (C2): 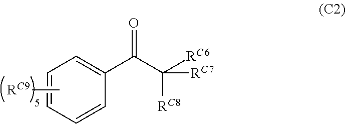
wherein R^{C6} represents a hydroxyl group, an alkoxy group having 1 to 6 carbon atoms, or an amino group,
wherein R^{C7} and R^{C8} each independently represents a hydrogen atom, an alkyl group having 1 to 8 carbon atoms, an aryl group having 6 to 12 carbon atoms, or an alkoxy group having 1 to 8 carbon atoms, or alternatively, R^{C7} and R^{C8} are optionally bonded to each other to form a cyclic structure having 3 to 16 carbon atoms,
wherein each instance of R^{C9} independently represents a hydrogen atom, a halogen atom, a hydroxyl group, an amino group, a mercapto group, or an organic group having 1 to 10 carbon atoms which optionally contains one or more atoms selected from an oxygen atom, a nitrogen atom, and a sulfur atom, and
wherein each of R^{C6} to R^{C8} other than the hydroxyl group and the hydrogen atom optionally has a substituent, in which case the substituents in an amino group are optionally bonded to each other to form a cyclic structure having 3 to 12 carbon atoms.

26. The photosensitive resin composition according to claim 12,
wherein the component (A) comprises a urethane (meth)acrylate having 6 or more (meth)acryloyl groups,
the component (D) comprises a benzotriazole-based compound, and
the component (F) comprises a silane coupling agent.

27. The method according to claim 14,
wherein the photosensitive layer comprises a sensitizer, and
wherein the irradiation is carried out with the active ray having a predetermined wavelength in the presence of the sensitizer.

28. The method according to claim 27, wherein a light source of the active ray having a predetermined wavelength is a semiconductor laser configured to emit a light with the predetermined wavelength as a main wavelength.

29. The method according to claim 27, wherein the sensitizer is a triazole.

30. The method according to claim 21,
wherein the photosensitive layer comprises a sensitizer, and
wherein the irradiation is carried out with the active ray having a predetermined wavelength in the presence of the sensitizer.

31. The method according to claim 30, wherein a light source of the active ray having a predetermined wavelength is a semiconductor laser configured to emit a light with the predetermined wavelength as a main wavelength.

32. The method according to claim 30, wherein the sensitizer is a triazole.
